(19) United States
(12) Patent Application Publication
(10) Pub. No.: US 2024/0381618 A1
(43) Pub. Date: Nov. 14, 2024

(54) SEMICONDUCTOR DEVICES

(71) Applicant: Samsung Electronics Co., Ltd., Suwon-si (KR)

(72) Inventors: Jongmin Kim, Suwon-si (KR); Myeongdong Lee, Suwon-si (KR); Seungbo Ko, Suwon-si (KR); Donghyuk Ahn, Suwon-si (KR)

(21) Appl. No.: 18/637,650

(22) Filed: Apr. 17, 2024

(30) Foreign Application Priority Data
May 11, 2023 (KR) 10-2023-0060845

(51) Int. Cl. H10B 12/00

(52) U.S. Cl. CPC H10B 12/315; H10B 12/482

(57) ABSTRACT

A semiconductor device includes a first contact structure on a central portion of the active pattern, a bit line structure on the first contact structure, a spacer structure on sidewalls of the bit line structure and the first contact structure and including a first spacer, a second spacer, an etch stop pattern and a third spacer sequentially stacked in a horizontal direction substantially parallel to an upper surface of the substrate, a second contact structure on an end portion of the active pattern, and a capacitor on the second contact structure. A lowermost surface of the first spacer may be lower than a lowermost surface of the second spacer, and lower surfaces of the etch stop pattern and the third spacer may be higher than the lowermost surface of the second spacer.

### CROSS-REFERENCE TO RELATED APPLICATION

This application claims priority under 35 U.S.C. § 119 to Korean Patent Application No. 10-2023-0060845 filed on May 11, 2023 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a DRAM device.

### DISCUSSION OF RELATED ART

A DRAM device includes gate structures which extend through upper portions of active patterns in a first direction, bit line structures on central portions of the active patterns, each of which extends in a second direction, contact plug structures on opposite end portions, respectively, of corresponding ones of the active patterns, and capacitors on corresponding ones, respectively, of the contact plug structures.

As the DRAM device has been highly integrated, an area of the contact plug structure contacting the active pattern decreases, so that an electrical connection between the contact plug structure and the active pattern may be poor.

### SUMMARY

Example embodiments provide a semiconductor device having improved electrical characteristics.

According to example embodiments, there is provided a semiconductor device. The semiconductor device may include a first conductive contact on a central portion of an active pattern, a bit line structure on the first conductive contact, a spacer structure on sidewalls of the bit line structure and the first conductive contact and including a first spacer, a second spacer, an etch stop pattern and a third spacer sequentially stacked in a horizontal direction parallel to an upper surface of the substrate, a second conductive contact on an end portion of the active pattern, and a capacitor on the second conductive contact. A lowermost surface of the first spacer may be lower than a lowermost surface of the second spacer, and lower surfaces of the etch stop pattern and the third spacer may be higher than the lowermost surface of the second spacer.

According to example embodiments, there is provided a semiconductor device. The semiconductor device may include an active pattern on a substrate, a first conductive contact on a central portion of the active pattern, a buffer stack on the substrate adjacent to the first conductive contact, a bit line structure on the first conductive contact and the buffer stack, a spacer structure on sidewalls of the bit line structure, the first conductive contact and the buffer stack and including a first spacer, a second spacer, an etch stop pattern and a third spacer sequentially stacked in a horizontal direction parallel to an upper surface of the substrate, a second conductive contact on an end portion of the active pattern and including a lower portion and an upper portion arranged along a vertical direction perpendicular to the upper surface of the substrate, and a capacitor on the second conductive contact. The first spacer may cover the sidewall of the bit line structure, the sidewall of the first conductive contact and an upper sidewall of the buffer stack. The etch stop pattern and the third spacer may contact an upper surface of the lower portion of the second conductive contact, and may cover a sidewall of the upper portion of the second conductive contact.

According to example embodiments, there is provided a semiconductor device. The semiconductor device may include active patterns on a substrate, an isolation pattern on the substrate and covering sidewalls of the active patterns, gate structures, each of which may extend through the active patterns and an upper portion of the isolation pattern in a first direction parallel to an upper surface of the substrate, spaced apart from each other in a second direction parallel to the upper surface of the substrate and perpendicular to the first direction, first conductive contacts on central portions of the active patterns, respectively, second conductive contacts on end portions of the active patterns, respectively, buffer stacks on the active patterns and the isolation pattern between the second conductive contacts, bit line structures, each of which may extend in the second direction on the first conductive contacts and the buffer stacks, spaced apart from each other in the first direction, spacer structures on sidewalls in the first direction of the bit line structures, the first conductive contacts and the buffer stacks, each of the space structures including a first spacer, a second spacer, an etch stop pattern and a third spacer sequentially stacked in the first direction, landing pads on the second conductive contacts, respectively, and capacitors on the second conductive contacts, respectively. A lowermost surface of the first spacer may be lower than a lowermost surface of the second spacer, and lower surfaces of the etch stop pattern and the third spacer may be higher than the lowermost surface of the second spacer.

In the semiconductor device in accordance with example embodiments, only some parts of the spacer structure may be formed on the sidewall of each of the bit line structures, and an etching process may be performed using the bit line structure and the parts of the spacer structure as an etching mask to form openings exposing upper surfaces of the end portions of the active patterns, so that a space between the bit line structures may be large enough to easily form the openings.

Additionally, residue in the openings may be removed by a cleaning process to enlarge the openings, so that heights of bottoms of the openings may have small distribution. Accordingly, lower surfaces of conductive contacts that may be formed in the respective openings may have small distribution, and the capacitors electrically connected to the active patterns through the conductive contacts may have uniform electrical characteristics.

### BRIEF DESCRIPTION OF THE DRAWINGS

FIGS. 1 to 3 are a plan view and cross-sectional views illustrating a semiconductor device in accordance with example embodiments.

FIGS. 4 to 43 are plan views and cross-sectional views illustrating a method of manufacturing a semiconductor device in accordance with example embodiments.

### DETAILED DESCRIPTION

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Hereinafter, two directions among horizontal directions that are substantially parallel to an upper surface of a substrate, which may be substantially perpendicular to each other, may be referred as first and second directions D1 and D2, respectively, and a direction among the horizontal directions, which may have an acute angle with respect to each of the first and second directions D1 and D2, may be referred to as a third direction D3.

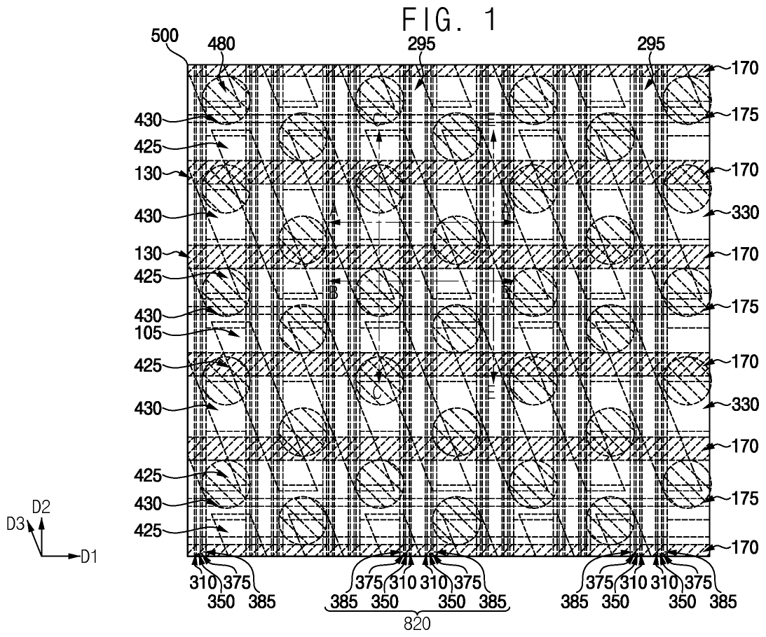

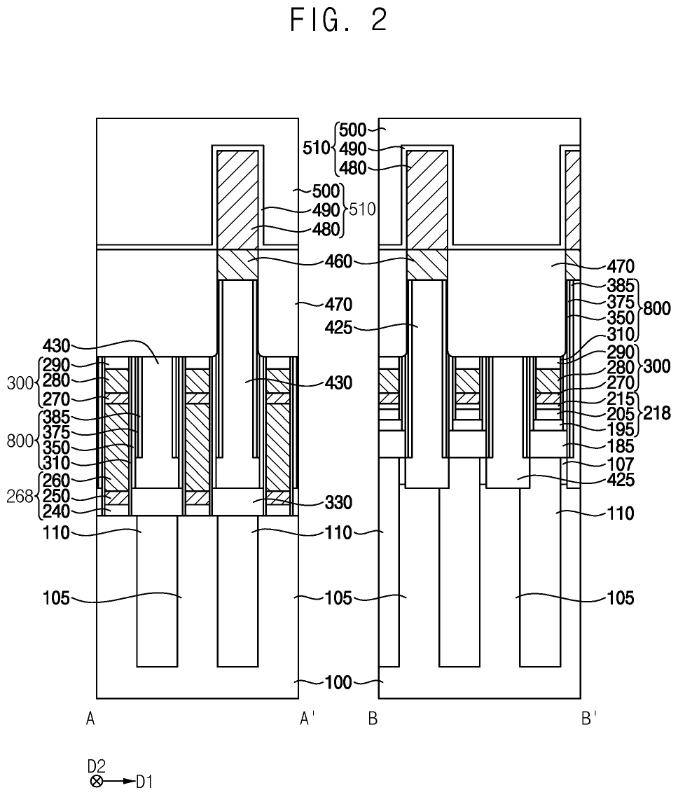

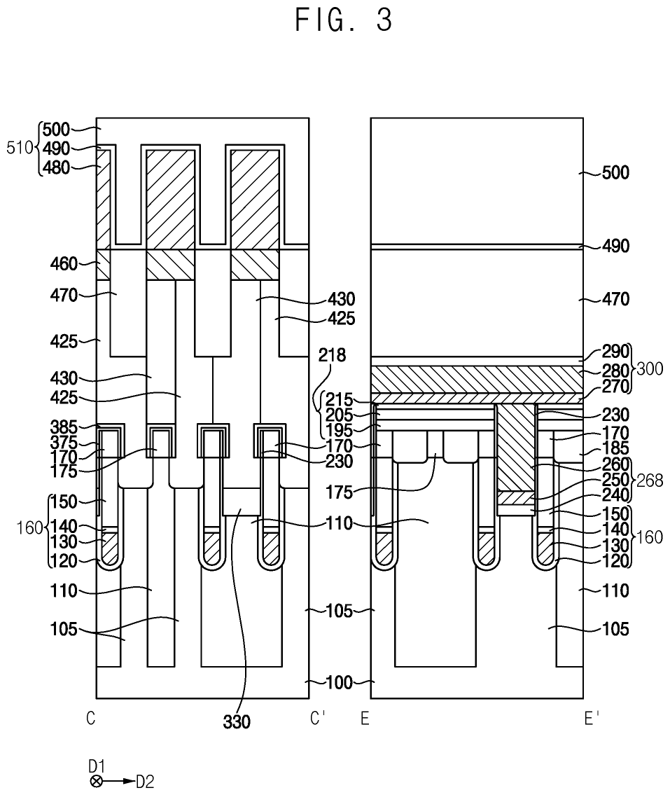

FIGS. 1 to 3 are a plan view and cross-sectional views illustrating a semiconductor device in accordance with example embodiments. Specifically, FIG. 1 is the plan view, FIG. 2 includes cross-sectional views taken along lines A-A′ and B-B′, respectively, of FIG. 1, and FIG. 3 includes cross-sectional views taken along lines C-C′ and E-E′, respectively, of FIG. 1.

Referring to FIGS. 1 to 3, the semiconductor device may include an active pattern 105, a gate structure 160, a bit line structure 300, a spacer structure 800, a buffer structure 218, a filling pattern 330, a first contact structure 268, a fence pattern 430, a second contact structure 425, a landing pad 460 and a capacitor 510 on a substrate 100. It should be noted that items described in the singular herein, may be provided in plural, as can be seen in the various figures from the context in which they are described.

The semiconductor device may further include an isolation pattern 110, a first mold layer 170, a second mold layer 175, a third mold 185, a first spacer 230 and an insulation pattern 470. The substrate 100 may be or include silicon, germanium, silicon-germanium, or a III-V group compound semiconductor, e.g., GaP, GaAs, GaSb, etc. In example embodiments, the substrate 100 may be a silicon-on-insulator (SOI) substrate or a germanium-on-insulator (GOI) substrate. The active pattern 105 may be defined on the substrate 100, and a sidewall of the active pattern 105 may be covered by the isolation pattern 110 on the substrate 100.

The active pattern 105 may extend in the third direction D3 to a certain length, and a plurality of active patterns 105 may be spaced apart from each other in the first direction D1 to form an active pattern row. Additionally, a plurality of active pattern rows may be spaced apart from each other in the second direction D2 to form an active pattern array. In example embodiments, the active patterns 105 in each of the active pattern rows may be aligned with each other in the first direction D1. End portions of ones of the active patterns 105 disposed in the first direction D1, which may correspond to each other in the first direction D1, may be aligned with each other along the first direction D1. For example, each of the active patterns 105 may have two end portions and a central portion disposed along the third direction D3. Corresponding ones of end portions of the active patterns 105 may be in a row and may be aligned with a straight line which is parallel to the first direction D1.

The active pattern 105 may include or be formed of a material substantially the same as a material of the substrate 100, and the isolation pattern 110 may include or be an oxide, e.g., silicon oxide. An impurity region 107 may be disposed at an upper portion of the end portions of the active pattern 105. The impurity region 107 may include, for example, n-type impurities or p-type impurities.

In example embodiments, an upper surface of the central portion of the active pattern 105 and an upper surface of a portion of the isolation pattern 110 adjacent thereto in the first direction D1 may be lower than an upper surface of the end portion of the active pattern 105 and an upper surface of a portion of the isolation pattern 110 adjacent thereto in the first direction D1. An upper surface of the central portion of each of the active patterns 105 is lower than the end portions of the active patterns 105. The isolation pattern 110 may cover sidewalls of the active patterns 105.

Each gate structure 160 may extend in the first direction DI through upper portions of the active pattern 105 and the isolation pattern 110, and a plurality of gate structures 160 may be spaced apart from each other in the second direction D2. Each gate structure 160 may include a first conductive pattern 130, a second conductive pattern 140 and a first mask 150 sequentially stacked in a vertical direction substantially perpendicular to an upper surface of the substrate 100, and may further include a gate insulation pattern 120, which may cover sidewalls of the first conductive pattern 130, the second conductive pattern 140 and the first mask 150 and a lower surface of the first conductive pattern 130. The first conductive pattern 130 combined with the second conductive pattern 140 may be a gate.

The gate insulation pattern 120 may include or be formed of an oxide, e.g., silicon oxide, the first conductive pattern 130 may include or be formed of, e.g., a metal, a metal nitride, a metal silicide, etc., the second conductive pattern 140 may include or be formed of, e.g., polysilicon doped with n-type impurities or p-type impurities, and the first mask 150 may include or be formed of an insulating nitride, e.g., silicon nitride. In an embodiment, two adjacent gate structures 160 spaced apart from each other in the second direction D2 may extend through an upper portion of corresponding one of the active pattern rows.

In another embodiment, a dummy gate structure (not shown in the drawings) extending in the first direction D1 through an upper portion of the isolation pattern 110 between the active pattern rows and an upper portion of each of the active patterns 105 adjacent to the upper portion of the isolation pattern 110 may be further disposed. For example, the dummy gate structure may be further disposed between the active pattern rows. The dummy gate structure may extend in the first direction D1 through an upper portion of the isolation pattern 110 and the active patterns 105, which are between the active pattern rows.

The first contact structure 268, also described as a first contact 268 or a conductive contact, may be disposed on the central portion of the active pattern 105, and may include a pad 240, an ohmic contact pattern 250 and a second metal pattern 260 sequentially stacked in the vertical direction. The first contact structure 268 (e.g., conductive contact) may include one or more conductive materials that form a continuous conductive structure extending vertically. In example embodiments, a plurality of first contact structures 268 may be spaced apart from each other in the first and second directions D1 and D2. The pad 240 may include or be, e.g., polysilicon doped with impurities, the ohmic contact pattern 250 may include or be a metal silicide, e.g., cobalt silicide, nickel silicide, titanium silicide, etc., and the second metal pattern 260 may include or be a metal, e.g., tungsten, niobium, copper, aluminum, etc.

The first mold layer 170, the second mold layer 175 and the third mold 185 may be disposed on the active pattern 105 and the isolation pattern 110. Each of the first and second mold layers 170 and 175 may extend in the first direction D1. A plurality of first mold layers 170 may be spaced apart from each other in the second direction D2, and a plurality of second mold layers 175 may be spaced apart from each other in the second direction D2. A plurality of third molds 185 may be spaced apart from each other in the first and second directions D1 and D2, and the third molds 185 may be disposed under the bit line structure 300.

In example embodiments, upper surfaces of the first and second mold layers 170 and 175 and an upper surface of the third mold 185 may be substantially coplanar with each other. Also, the third mold 185 may have a lower surface lower than lower surfaces of the first and second mold layers 170 and 175. The etch stop pattern 375 may contact a sidewall of the third mold 185 in the first directions D1. The first mold layer 170 and the second mold layer 175 may include or be formed of an insulating nitride, e.g., silicon nitride, and the third mold 185 may include an oxide, e.g., silicon oxide.

The buffer structure 218 may be disposed between the bit line structure 300 and the first and second mold layers 170 and 175 and the third mold 185. The buffer structure 218 may include first to third buffers 195, 205 and 215 sequentially stacked in the vertical direction. The buffer structure 218 may be a buffer stack. The buffer structure 218 may be disposed lower than the bit line structure 300 in the vertical direction. The buffer structure 218 may be disposed higher that the first mold layers 170, the second mold layers 175 and the third mold 185 in the vertical direction. A plurality of buffer structures 218 may be spaced apart from each other in the first and second directions D1 and D2. The first buffer 195 may include or be an oxide, e.g., silicon oxide, the second buffer 205 may include or be a high-k material, and the third buffer 215 may include or be a nitride, e.g., silicon nitride. An upper surface of the buffer structure 218 may be substantially coplanar with an upper surface of the first contact structure 268. In one embodiment, a lower surface of the buffer structure 218 is higher than a lower surface of the first contact structure 268.

The bit line structure 300 may extend in the second direction D2, and a plurality of bit line structures 300 may be spaced apart from each other in the first direction D1. The bit line structure 300 may overlap the central portion of the active pattern 105 in the vertical direction, and the first contact structure 268 may be disposed between the bit line structure 300 and the active pattern 105. The bit line structure 300 may contact an upper surface of the buffer structure 218.

The bit line structure 300 may include a barrier pattern 270, a third metal pattern 280 and a second mask 290 sequentially stacked in the vertical direction. The barrier pattern 270 may include or be a metal nitride, e.g., titanium nitride or a metal silicon nitride, e.g., titanium silicon nitride, the third metal pattern 280 may include or be a metal, e.g., tungsten, and the second mask 290 may include an insulating nitride, e.g., silicon nitride. The combined barrier pattern 270 and third metal pattern 280 may be a bit line.

The filling pattern 330 may be disposed on a portion of the isolation pattern 110 adjacent to the central portion of the active pattern 105. The filling pattern 330 and the central portion of the active pattern 105 may be neighboring in the first direction D1, and may be disposed between the first contact structures 268 neighboring in the first direction D1. For example, the filling pattern 330 may be disposed between adjacent and neighboring two of the first contact structures 268 in the first direction D1. The plurality of filling patterns 330 may be spaced apart from each other in the second direction D2 between neighboring ones of the bit line structures 300 in the first direction D1. For example, the plurality of filling patterns 330 may be between neighboring two of the bit line structures 300 in a plan view. The filling patterns 330 and the bit line structures 300 may be alternatively neighboring in the first direction D1 in a plan view. Additionally, a plurality of filling patterns 330 may be spaced apart from each other in the first direction D1 between neighboring ones of the gate structures 160 in the second direction D2. For example, the filling patterns 330 may be between neighboring two of the gate structures 160, which extend in the second direction D2.

In example embodiments, a lower surface of the filling pattern 330 may be substantially coplanar with a lower surface of the central portion of the active pattern 105 and the lower surface of the first contact structure 268, and may be higher than an upper surface of the second conductive pattern 140 of the gate structure 160. Additionally, an upper surface of the filling pattern 330 may be lower than the upper surface of the end portion of the active pattern 105. The filling patterns 330 are disposed between a portion of the isolation pattern, which may be adjacent to the central portion of the active patterns 105, and the fence patterns. The filling patterns may cover a lower sidewall of the first contact structure 268. The filling patterns 330 may cover lower sidewalls of the first contact structures 268. The filling pattern 330 may include or be formed of an insulating nitride, e.g., silicon nitride or silicon oxycarbonitride.

The first spacer 230 may be disposed on a sidewall of the first mold layer 170 and a sidewall of the buffer structure 218. In some embodiments, the first spacer 230 may not be formed. The first spacer 230 may include or be formed of an insulating nitride, e.g., silicon nitride.

The spacer structure 800 may include a second spacer 310, a third spacer 350, an etch stop pattern 375 and a fourth spacer 385 sequentially stacked on a sidewall of the bit line structure 300 in the first direction D1. The spacer structure 800 may be disposed on each of opposite sidewalls of the bit line structure 300 and the first contact structure 268 in the first direction D1. In example embodiments, each of the second and third spacers 310 and 350 may extend in the second direction D2.

In example embodiments, the second spacer 310 may contact each of opposite sidewalls in the first direction D1 of the first contact structure 268 and each of opposite sidewalls in the first direction D1 of the bit line structure 300. Additionally, the second spacer 310 may also contact each of opposite sidewalls in the first direction D1 of each of the second and third buffers 205 and 215. The second spacer 310 may also contact an upper surface of each of the end portions in the first direction D1 of the first buffer 195.

Thus, a lowermost surface of the second spacer 310 may be substantially coplanar with the upper surface of the central portion of the active pattern 105, the upper surface of the portion of the isolation pattern 110 adjacent thereto in the first direction D1, and the lower surface of the filling pattern 330.

In example embodiments, the third spacer 350 may contact each of opposite sidewalls in the first direction D1 of the second spacer 310 and each of opposite sidewalls in the first direction D1 of the first buffer 195. Additionally, the third spacer 350 may also contact an upper surface of each of opposite end portions in the first direction D1 of the third mold 185. The third spacer 350 may also contact an upper surface of each of opposite end portions in the first direction D1 of the filling pattern 330. Thus, a lowermost surface of the third spacer 350 may be substantially coplanar with the upper surface of the filling pattern 330, and may be higher than the lower surface of the second spacer 310.

The etch stop pattern 375 and the fourth spacer 385 may be sequentially stacked on each of opposite sidewalls in the first direction D1 of the third spacer 350, each of opposite sidewalls in the first direction D1 of the third mold 185. The etch stop pattern 375 and the fourth spacer 385 may be sequentially stacked on each of opposite sidewalls in the second direction D2 of the first and second mold layers 170 and 175. The etch stop pattern 375 and the fourth spacer 385 may be sequentially stacked on upper surfaces of the first and second mold layers 170 and 175 in the vertical direction, and may be sequentially stacked on an outer sidewall in the second direction D2 of the first spacer 230.

In example embodiments, a lower surface of the etch stop pattern 375 and a lower surface of the fourth spacer 385 may be substantially coplanar with the upper surface of the end portion of the active pattern 105, and thus may be higher than the lowermost surface of the third spacer 350. In example embodiments, the lowermost surface of the second spacer 310 is lower than the lowermost surface of the third spacer 350, and the lower surfaces of the etch stop pattern 375 and the fourth spacer 385 are higher than the lowermost surface of the third spacer 350. The lowermost surface of the etch stop pattern 375 may be substantially coplanar with the lowermost surface of the fourth spacer 385. The etch stop pattern may 375 may contact an outer sidewall of the third spacer 350. Each of the second spacer 310 and the fourth spacer 385 may include or be formed of an insulating nitride, e.g., silicon nitride, and each of the third spacer 350 and the etch stop pattern 375 may include or be formed of an oxide, e.g., silicon oxide.

The second contact structure 425, also described as a second contact 268 or a conductive contact, may be disposed on each of opposite end portions of the active pattern 105, and may contact the impurity region 107. A plurality of second contact structures 425 may be spaced apart from each other in the first and second directions D1 and D2. The second contact structure 425 (e.g., conductive contact) may include one or more conductive materials that form a continuous conductive structure extending vertically.

In example embodiments, the second contact structure 425 may include a lower portion having a first width in the first direction D1. The second contact structure 425 may include an upper portion on the lower portion, which may be arranged along the vertical direction. The upper portion of the second contact structure 425 may have a second width in the first direction D1 less than the first width. Due to the width difference, the lower portion of the second contact structure 425 may protrude from and a sidewall of the upper portion of the second contact structure 425 so as to have a step-like shape. Due to the protrusion and the step-like shape, the lower portion of the second contact structure 425 may have an upper surface (i.e., surface of the step-like shape) at an edge that defines a top of the lower portion of the second contact structure 425. The lower portion of the second contact structure 425 may contact the active pattern 105 and a portion of the isolation pattern 110 adjacent thereto. The sidewall of the upper portion of the second contact structure 425 may be covered by the fourth spacer 385. In example embodiments, the lower surface of the etch stop pattern 375 and the lower surface of the fourth spacer 385 may contact the upper surface at the edge of the lower portion of the second contact structure 425. The third spacer 350 may cover an upper sidewall of the first contact structure 268, and the lowermost surface of the third spacer 350 is substantially coplanar with a lower surface of the second contact structure 425. A lower surface of the etch stop pattern 375 and a lower surface of the fourth spacer 385 are substantially coplanar with an upper surface of the lower portion of the second contact structure 425. The second contact structure 425 may include, e.g., doped polysilicon.

The fence pattern 430 may be disposed on the filling pattern 330, and may also be disposed on a portion of the fourth spacer 385. The fence pattern 430 may also be disposed on a portion of the first mold layer 170 and the second mold layers 175. A portion of the fourth spacer 385 may be between the fence pattern 430 and the first mold layer 170. The portion of the fourth spacer 385 may be between the fence pattern 430 and the second mold layers 175. In example embodiments, a plurality of fence patterns 430 may be spaced apart from each other in the first and second directions D1 and D2.

The fence pattern 430 may include a lower portion having a third width in the first direction D1. The fence pattern 430 may include an upper portion on the lower portion having a fourth width in the first direction D1 less than the third width. The upper portion and the lower portion of fence pattern 430 may be arranged along the vertical direction. Lowermost and uppermost portions of the fence pattern 430 are substantially coplanar with lowermost and uppermost portions of the second contact structure 425, respectively. The lower portion and the upper portion of the fence pattern 430 may be substantially coplanar with the lower portion and the upper portion, respectively, of the second contact structure 425. In the vertical direction, a lowest portion (e.g., lowest surface) of the fence patterns 430 may be substantially coplanar with the lowest portion (e.g., lowest surface) of the second contact structures 425. In the vertical direction, a highest portion (e.g., highest surface) of the fence patterns 430 may be substantially coplanar with the highest portion (e.g., highest surface) of the second contact structures 425.

A lower surface of the lower portion of the fence pattern 430 may contact the upper surface of the filling pattern 330, and a sidewall in the first direction D1 of the lower portion of the fence pattern 430 may contact an outer sidewall of the third spacer 350. Additionally, a sidewall in the first direction of the upper portion of the fence pattern 430 may contact the fourth spacer 385, and a sidewall in the second direction D2 of the upper portion of the fence pattern 430 may contact the second contact structure 425. The fence pattern 430 may include an insulating nitride, e.g., silicon nitride, silicon oxycarbonitride, etc.

The landing pad 460 may contact the upper surface of the second contact structure 425, and a plurality of landing pads 460 may be spaced apart from each other in the first and second directions D1 and D2. In example embodiments, the landing pad 460 may have a shape of, e.g., a circle, an ellipse, a polygon, a polygon with rounded corners, etc., in a plan view, and the landing pads 460 may be arranged in a honeycomb pattern in a plan view. The landing pad 460 may include, e.g., a metal, a metal nitride, etc.

The insulation pattern 470 may cover sidewalls of the landing pads 460, and may partially extend through upper portions of the bit line structure 300, the second contact structure 425 and the fence pattern 430. The insulation pattern 470 may include an insulating nitride, e.g., silicon nitride.

The capacitor 510 may include a first electrode 480, a dielectric layer 490 and a second electrode 500 sequentially stacked, and the first electrode 480 may contact an upper surface of the landing pad 460. Each of the first and second electrodes 480 and 500 may include a metal, a metal nitride, a metal silicide, silicon-germanium doped with impurities, etc., and the dielectric layer 490 may include a metal oxide having a high dielectric constant.

In the semiconductor device, the bit line structure 300 may be electrically connected to the central portion of the active pattern 105 through the first contact structure 268, and the capacitor 510 may be electrically connected to the end portion of the active pattern 105 through the landing pad 460 and the second contact structure 425.

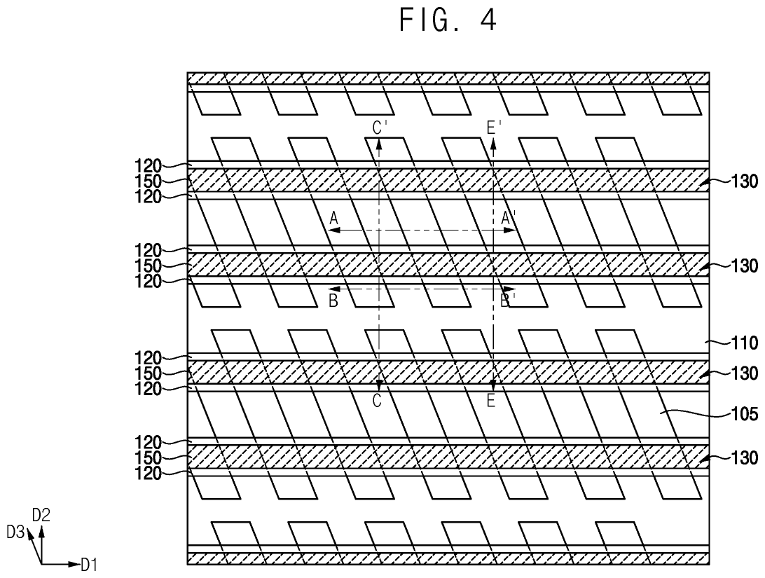

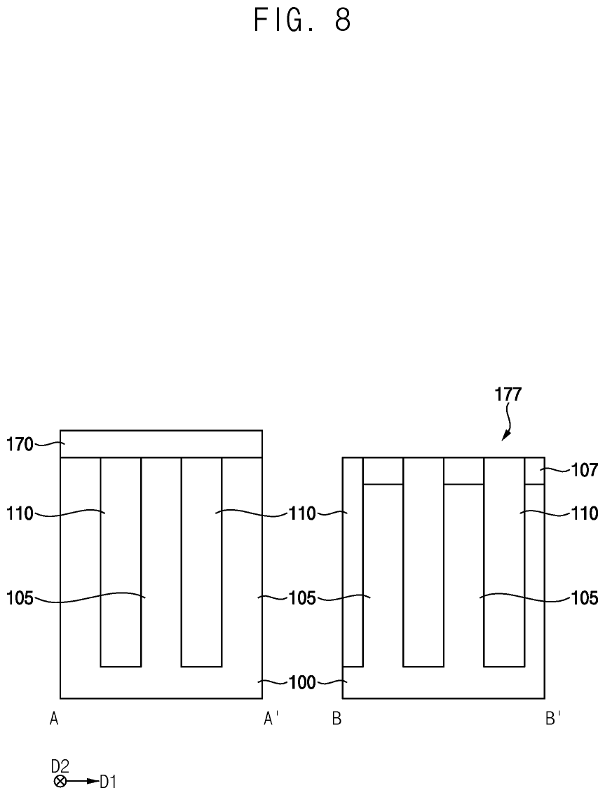

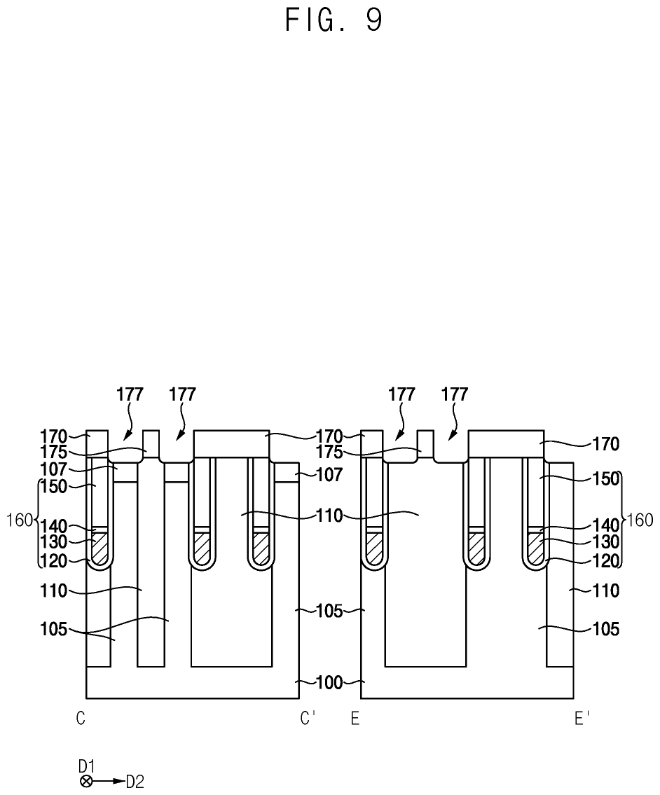

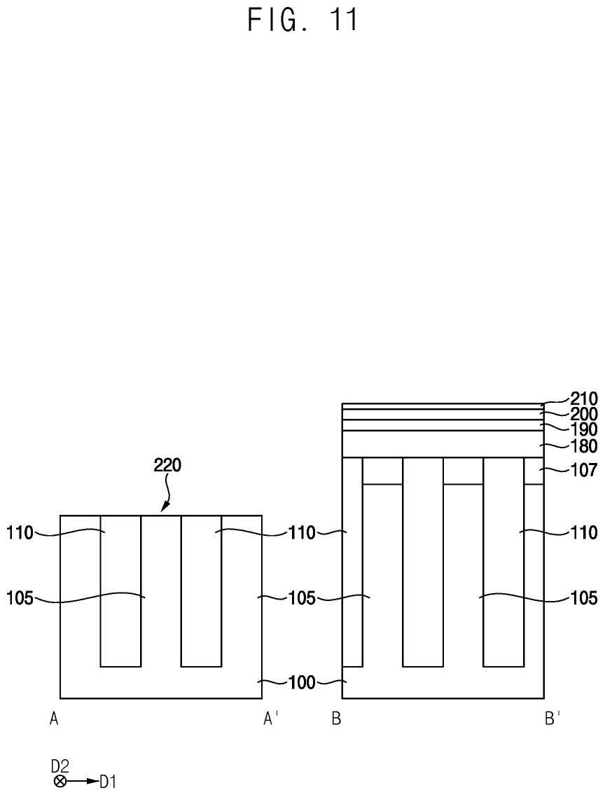

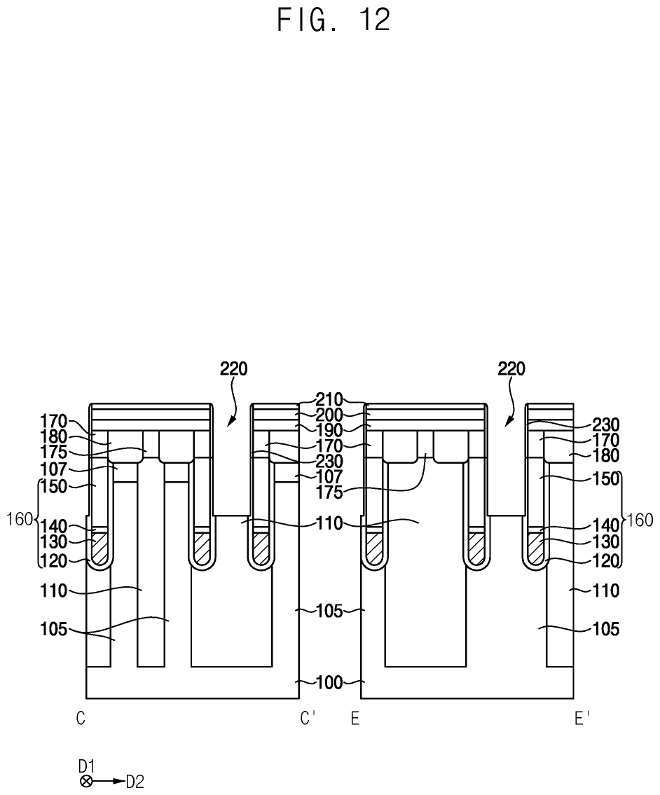

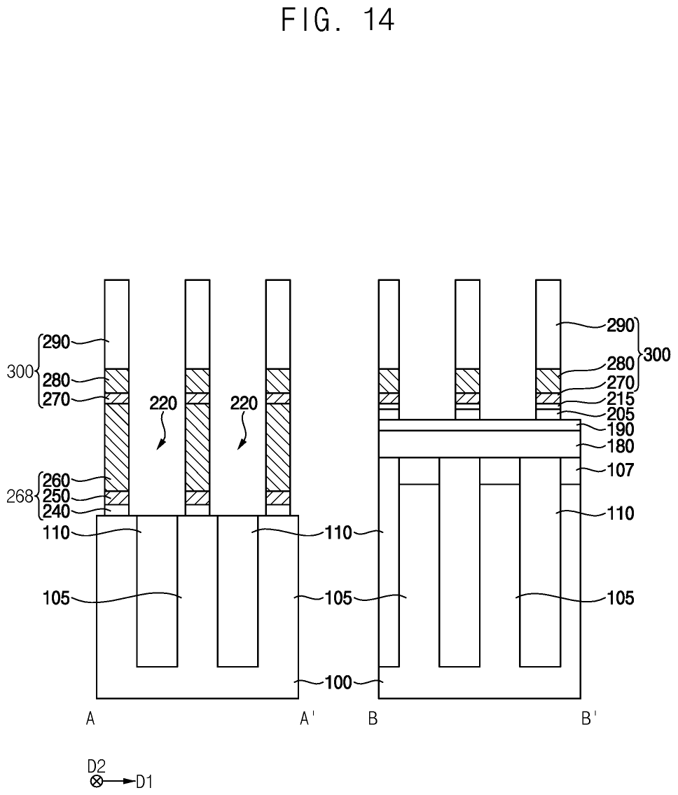

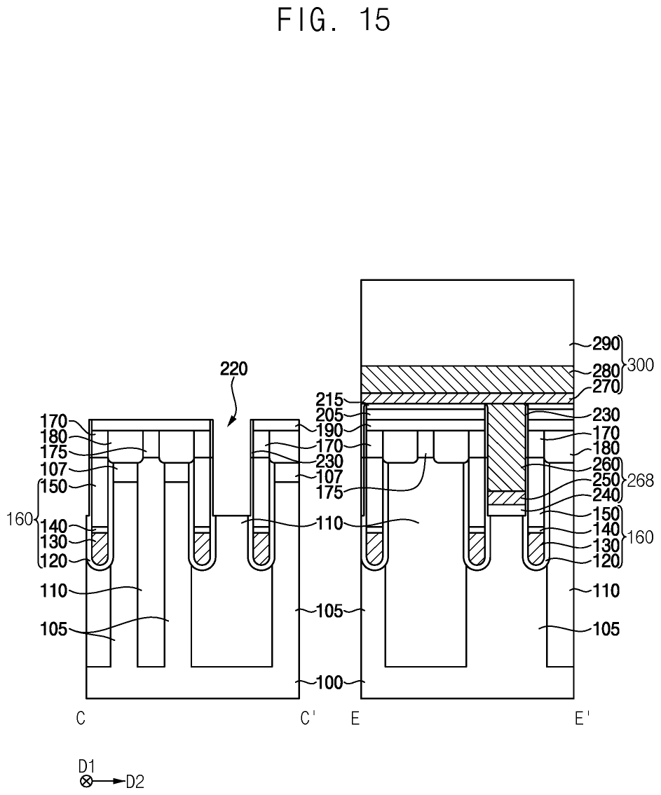

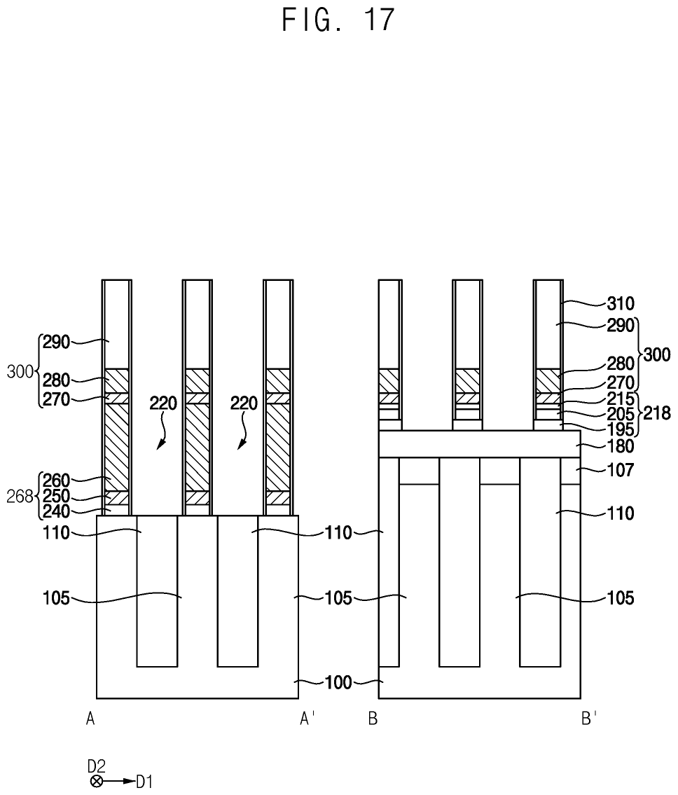

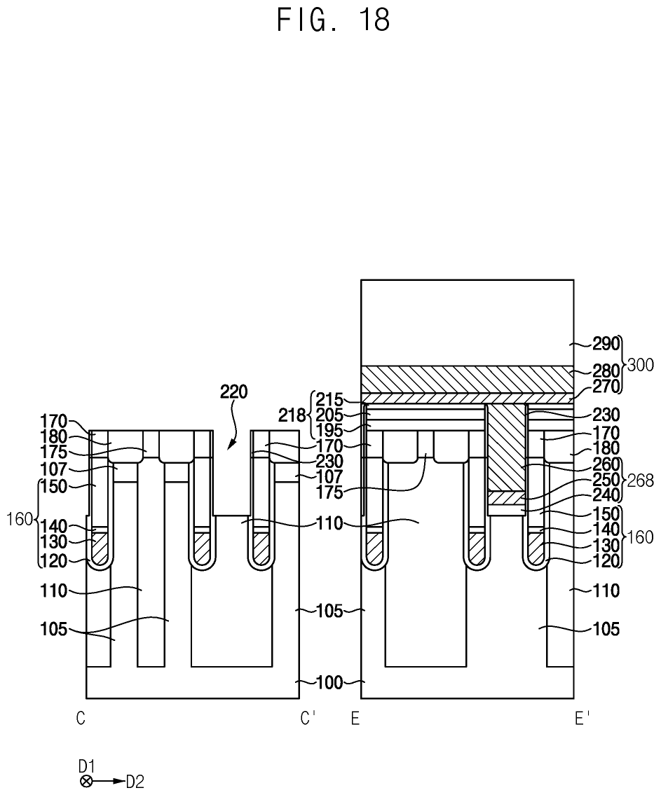

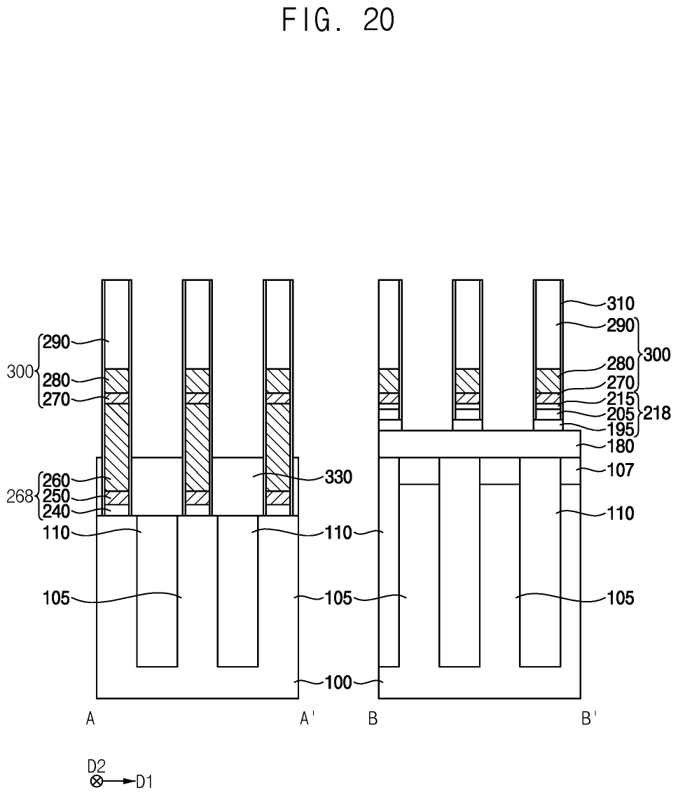

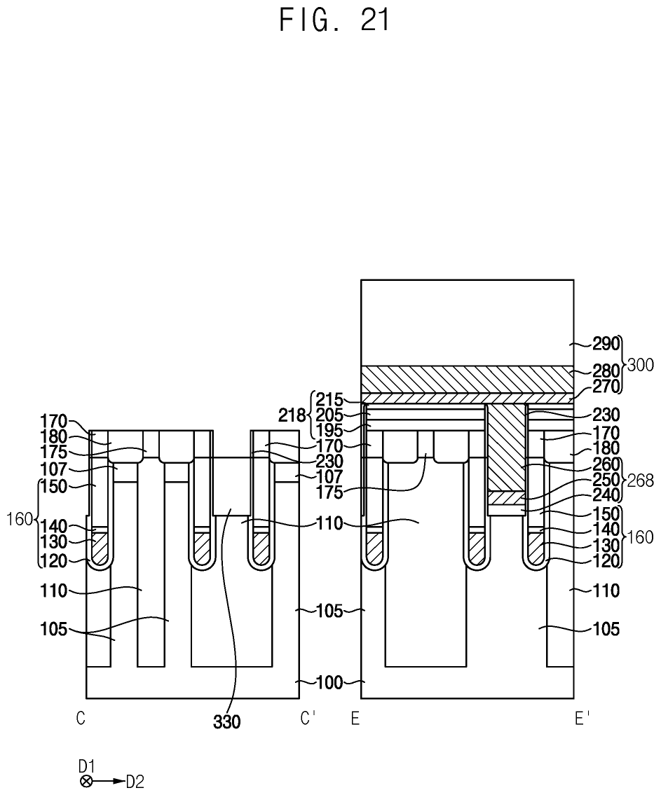

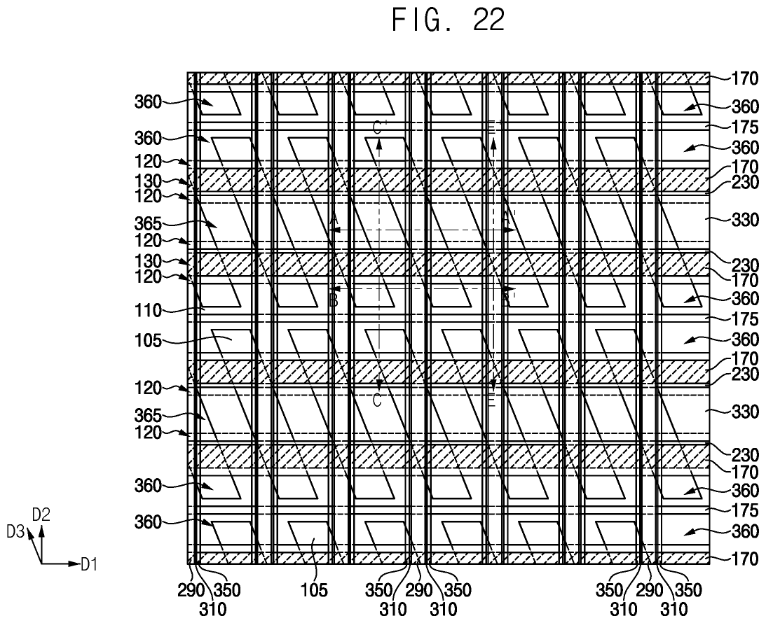

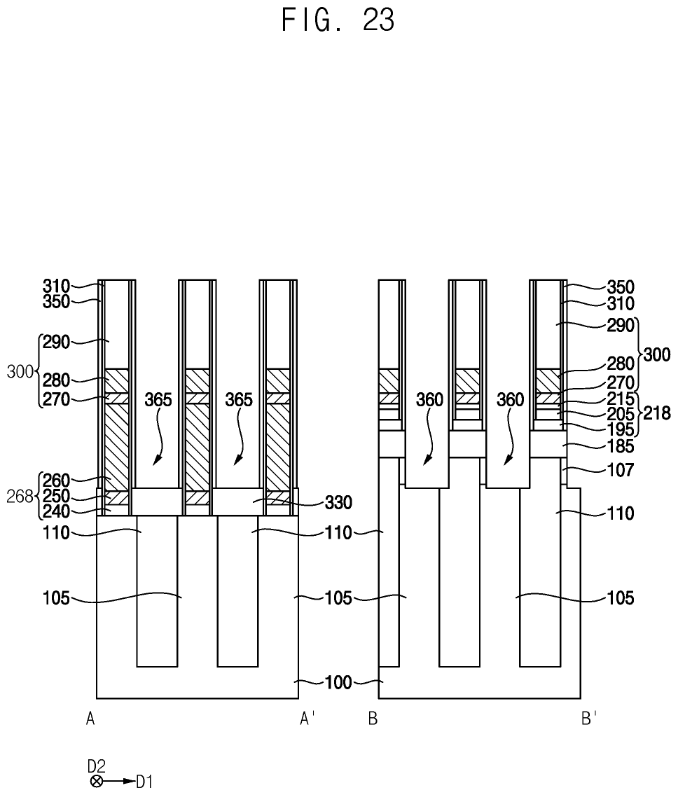

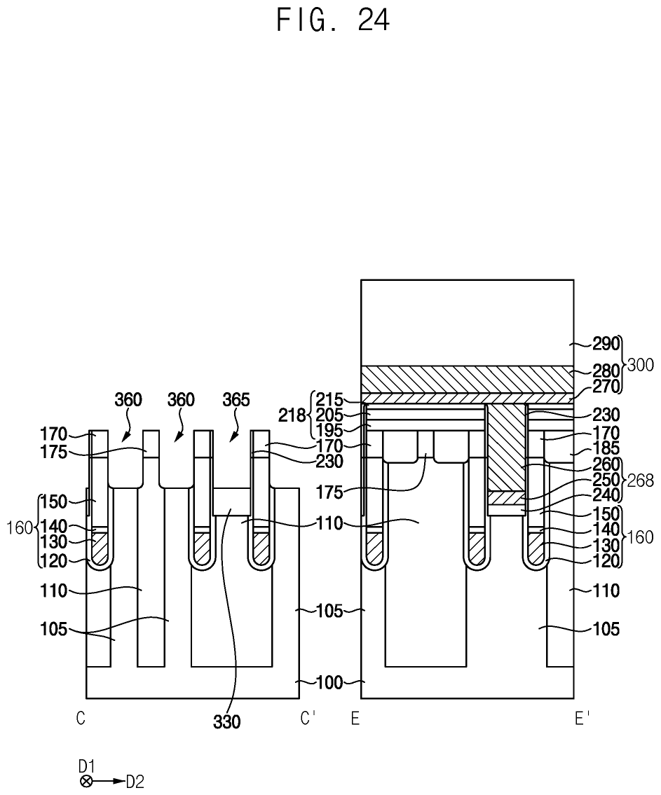

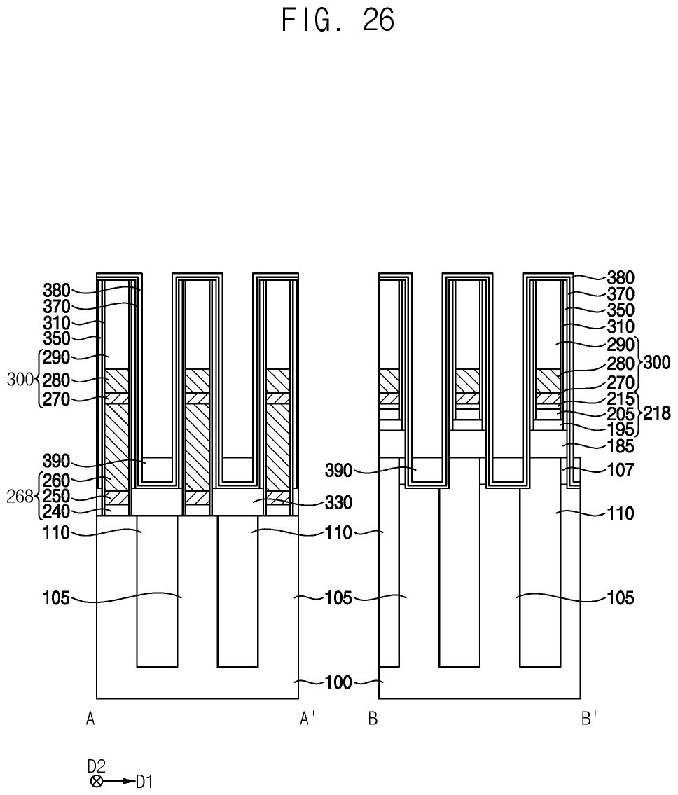

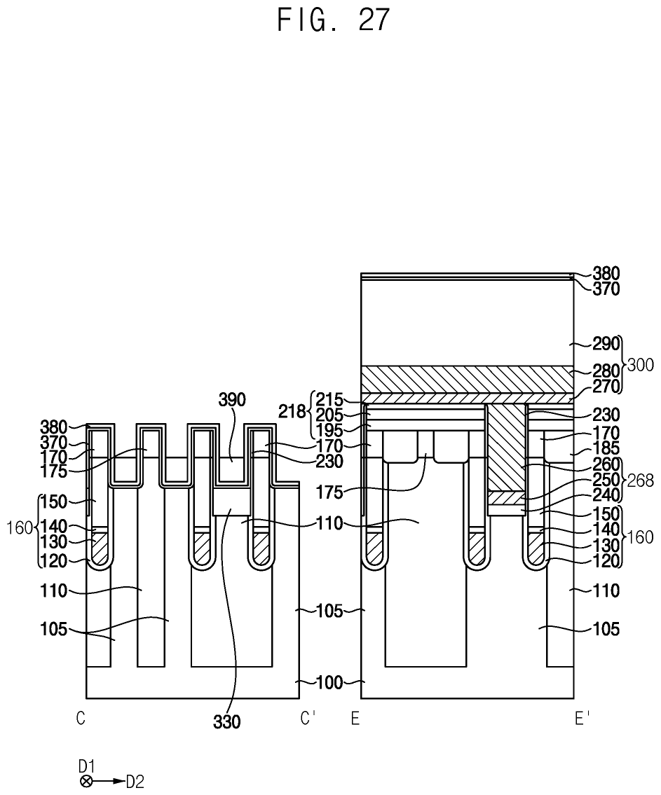

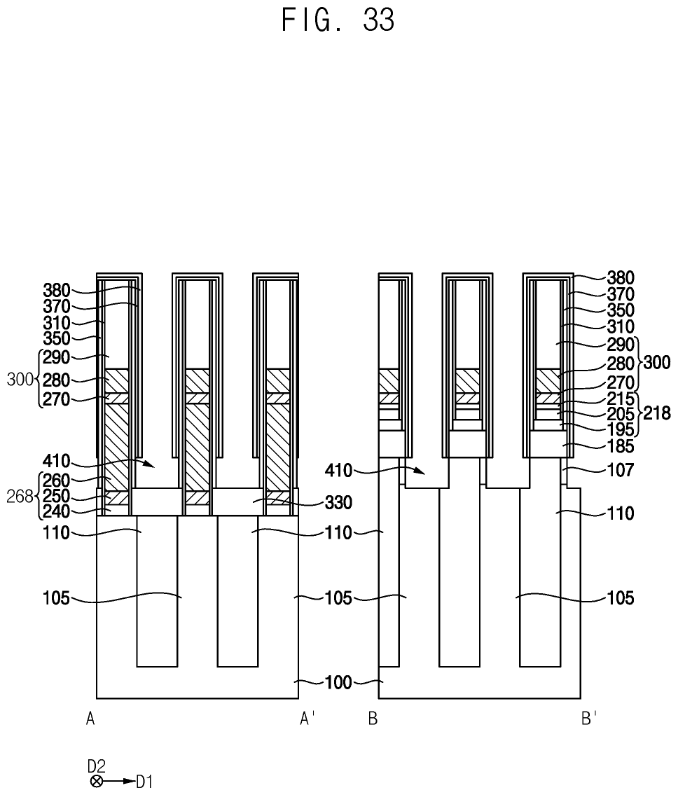

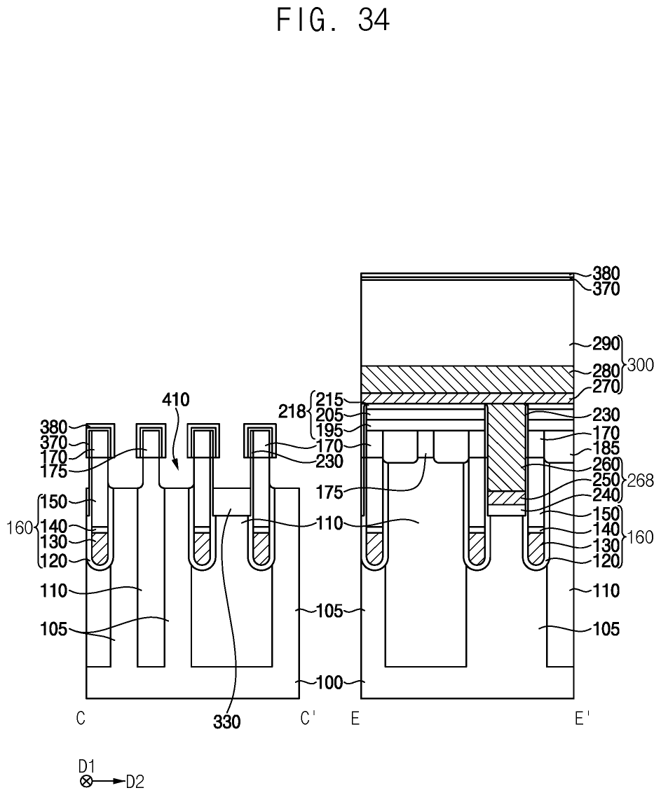

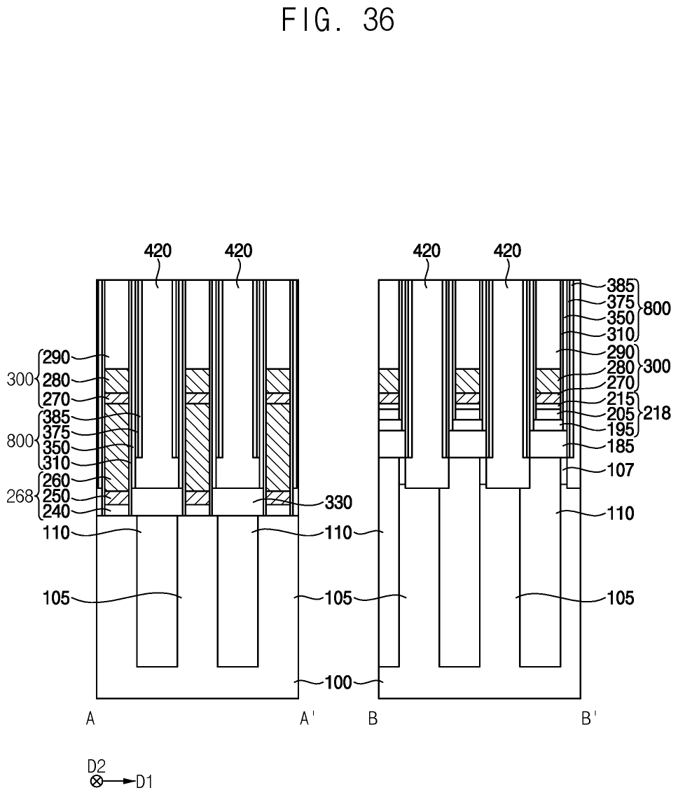

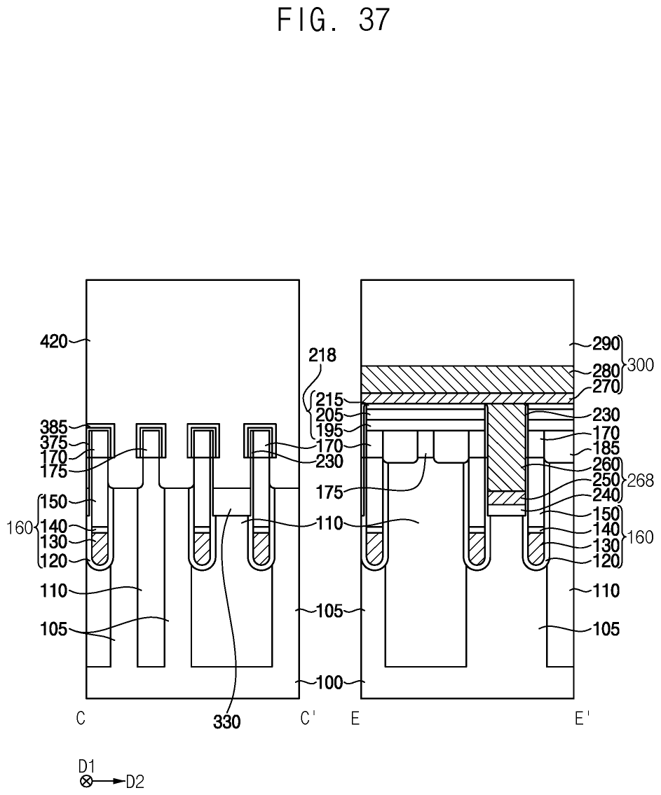

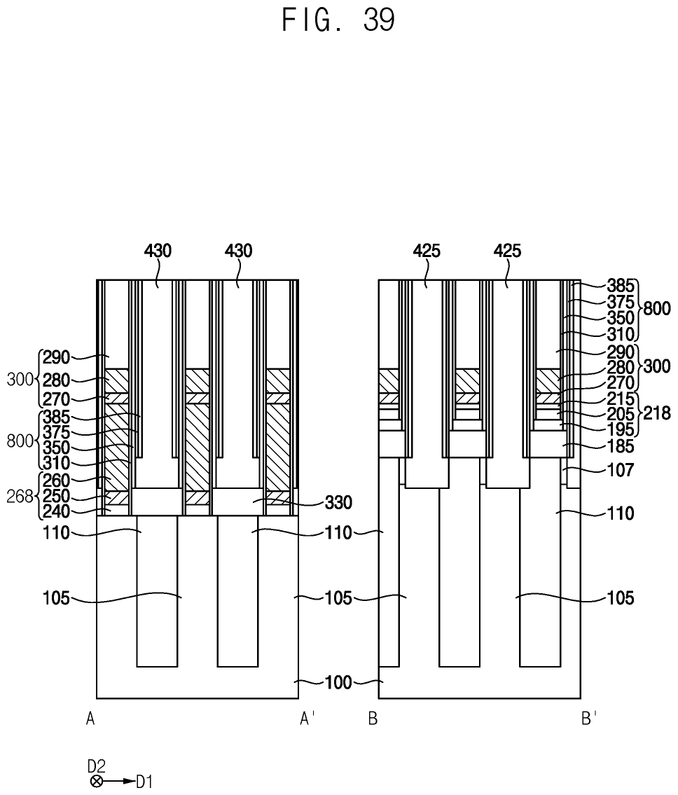

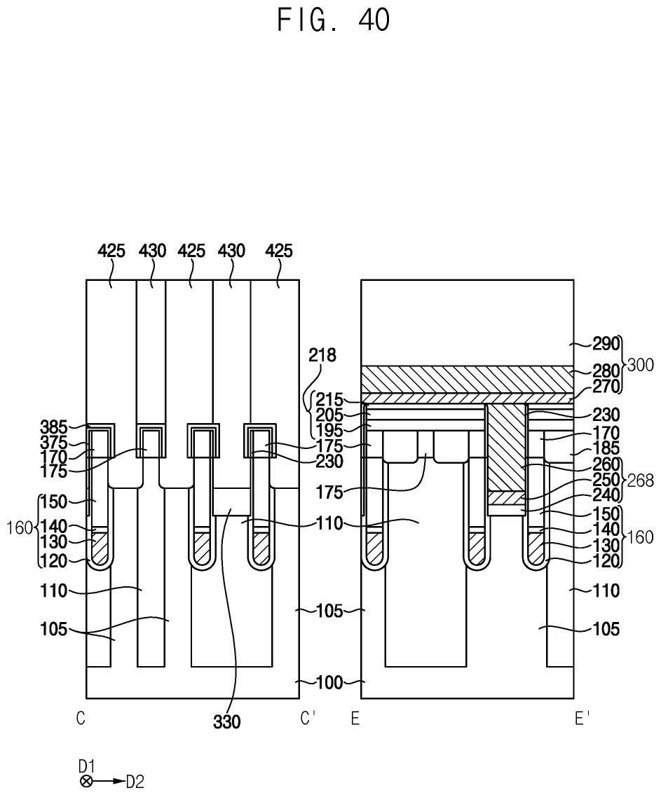

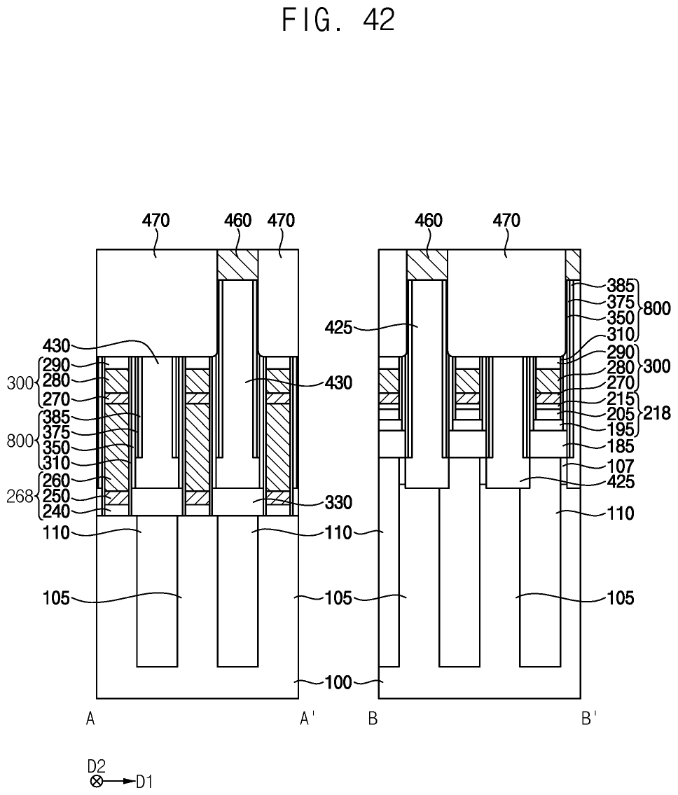

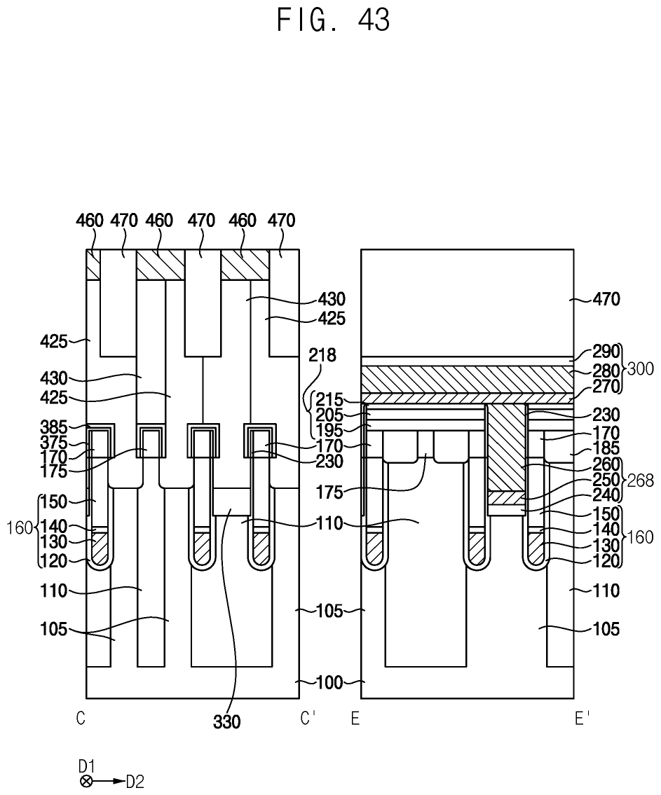

As illustrated below with reference to FIGS. 4 to 43, after the second and third spacers 310 and 350 may be formed on the sidewall of the bit line structure 300, an etching process may be performed using the second and third spacers 310 and 350 as an etching mask to form fourth openings 360 (refer to FIGS. 22 to 24) exposing upper surfaces of the end portions of the active patterns 105. Thus, a space between the bit line structures 300 may be provided so that the fourth openings 360 may be easily formed.

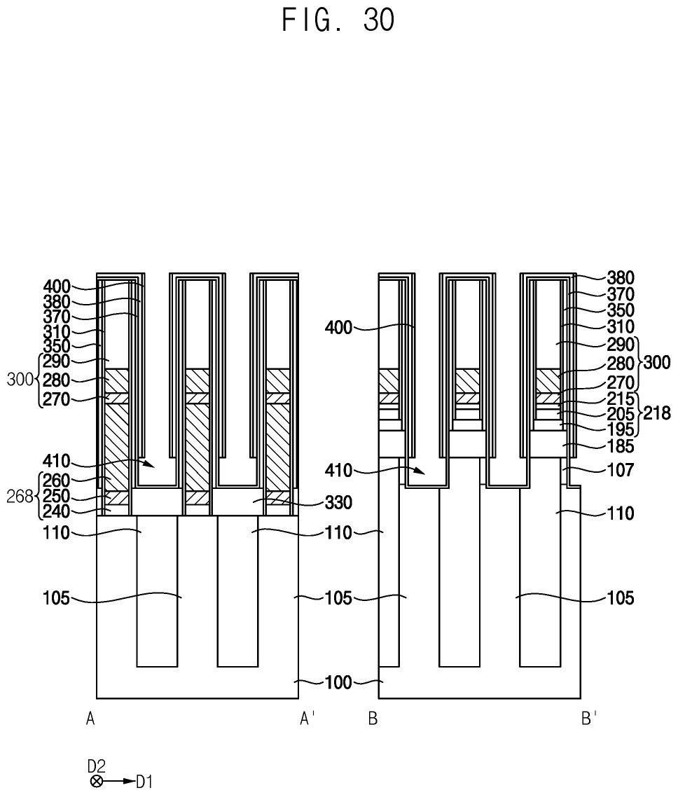

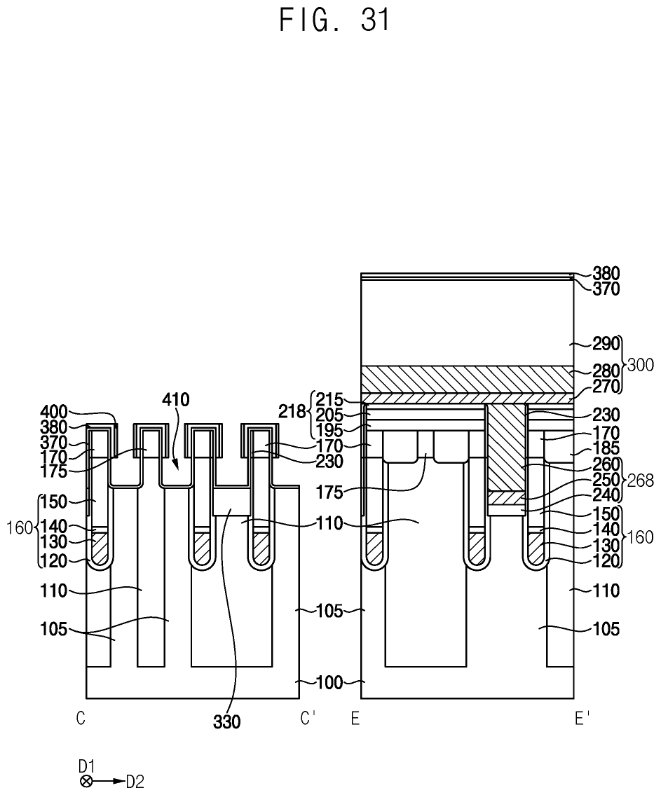

Additionally, layers in the fourth openings 360 may be easily removed by, e.g., a wet etching process. Accordingly, bottoms of fifth openings 410 (refer to FIGS. 30 and 31), which may be formed by removing the layers in the fourth opening 360, may have a small variation. Accordingly, the dimensional uniformity of the fifth openings 410 may be increased. Moreover, the capacitors 510, which may be electrically connected to the active patterns 105 through the second contact structures 425, may have uniform electric characteristics.

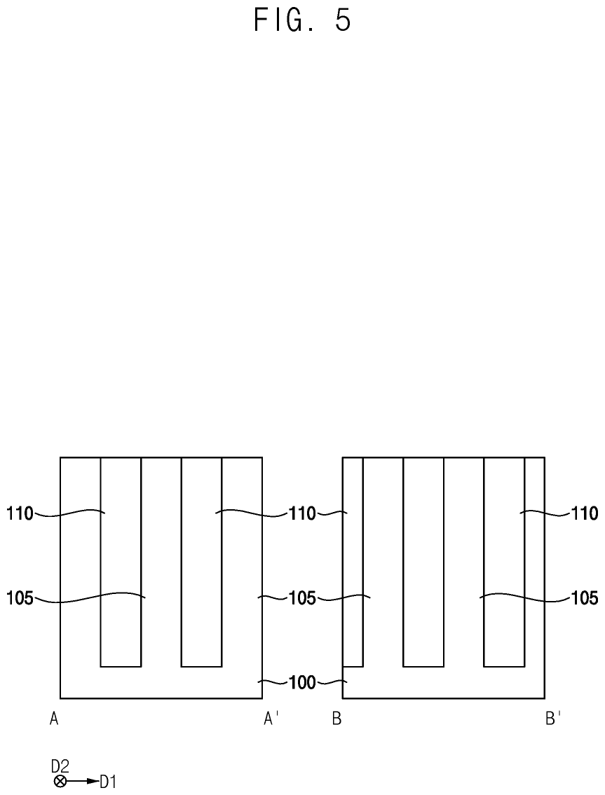

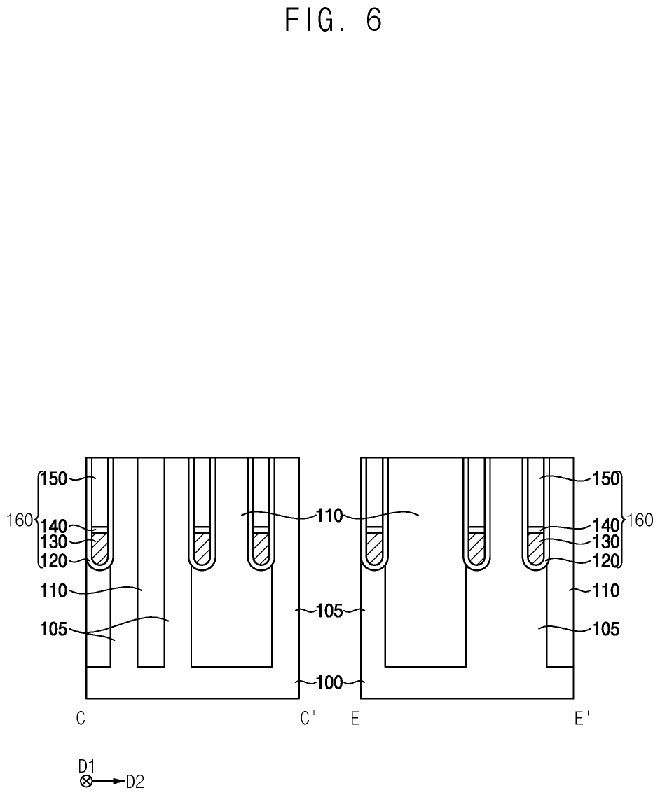

FIGS. 4 to 43 are plan views and cross-sectional views illustrating a method of manufacturing a semiconductor device in accordance with example embodiments. Specifically, FIGS. 4, 7, 10, 13, 16, 19, 22, 25, 32, 35, 38 and 41 are the plan views, each of FIGS. 5, 8, 11, 14, 17, 20, 23, 26, 28, 30, 33, 36, 39 and 42 includes cross-sectional views taken along lines A-A′ and B-B′, respectively, of a corresponding plan view, and each of FIGS. 6, 9, 12, 15, 18, 21, 24, 27, 29, 31, 34, 37, 40 and 43 includes cross-sectional views taken along lines C-C′ and E-E′, respectively, of a corresponding plan view.

Referring to FIGS. 4 to 6, an upper portion of a substrate 100 may be removed to form a recess structure so that an active pattern 105 may be defined, and an isolation pattern 110 may be formed to fill the recess structure. In an example embodiment, the recess structure may include a first recess extending in the third direction D3 and a second recess extending in the first direction D1 to be connected to the first recess.

In example embodiments, the active pattern 105 may extend in the third direction D3 to a certain length on the substrate 100, and a plurality of active patterns 105 may be spaced apart from each other in the first direction D1 to form an active pattern row. In addition, a plurality of active pattern rows may be spaced apart from each other in the second direction D2 on the substrate 100 to form an active pattern array.

Upper portions of the active pattern 105 and the isolation pattern 110 may be removed to form a third recess, and a gate insulation layer may be formed on an inner wall of the third recess. A first conductive layer may be formed on the gate insulation layer, an upper portion of the first conductive layer may be removed to form a first conductive pattern 130, a second conductive layer may be formed on the first conductive pattern 130 and the gate insulation layer, and an upper portion of the second conductive layer may be removed to form a second conductive pattern 140. A first mask layer may be formed on the second conductive pattern 140 and the gate insulation layer, and the first mask layer and the gate insulation layer may be planarized until an upper surface of the active pattern 105 and an upper surface of the isolation pattern 110 are exposed to form a first mask 150 and a gate insulation pattern 120, respectively. The gate insulation pattern 120, the first and second conductive patterns 130 and 140 and the first mask 150 in the third recess may collectively form a gate structure 160.

In example embodiments, the gate structure 160 may extend in the first direction D1, and a plurality of gate structures 160 may be spaced apart from each other in the second direction D2. In an example embodiment, two gate structures 160 spaced apart from each other in the second direction D2 may be formed at an upper portion of one of the active pattern rows. Hereinafter, a portion of the active pattern 105 between the two gate structures 160 may be referred to as a central portion thereof, and a portion of the active pattern 105 at an opposite side of the central portion of the active pattern 105 with respect to a corresponding one of the two gate structures 160 may be referred to as an end portion thereof. For example, each of the active patterns 105 may have a pair of the end portions and the central portion disposed along the third direction D3. In a plan view, the central portion disposed between a pair of the gate structures 160, and the pair of the end portions are disposed at opposite two ends of each of the active patterns 105 in the third direction D3.

In another example embodiment, a dummy gate structure (not shown in the drawings) extending in the first direction D1 through an upper portion of the isolation pattern 110 between the active pattern rows and the upper portion of each active pattern 105 adjacent to the upper portion of the isolation pattern 110 between the active pattern rows may be further formed.

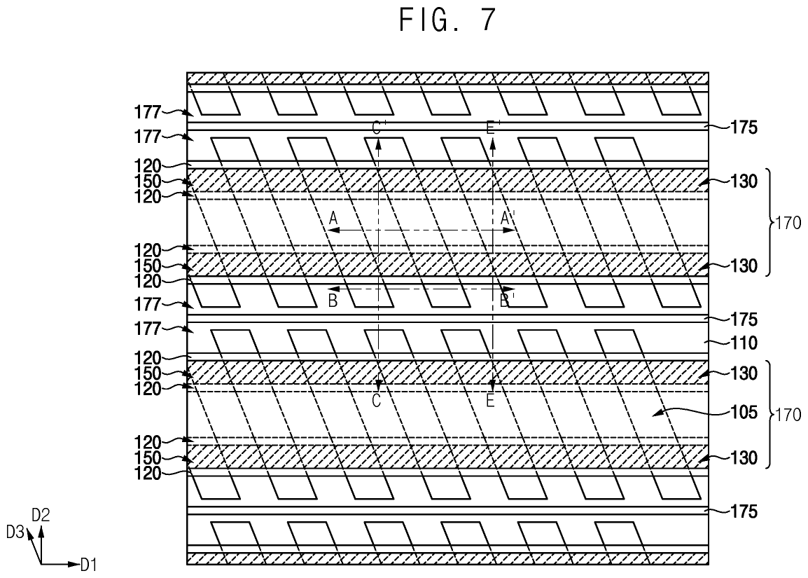

Referring to FIGS. 7 to 9, first and second mold layers 170 and 175 may be formed on the active pattern 105, the isolation pattern 110 and the gate structure 160, and a first opening 177 may be formed between the first and second mold layers 170 and 175. In example embodiments, each of the first and second mold layers 170 and 175 may extend in the first direction D1, and thus the first opening 177 may also extend in the first direction D1. The first mold layer 170 may cover upper surfaces of the two gate structures 160 extending through the upper portion of the active pattern 105, and the second mold layer 175 may cover an upper surface of a portion of the isolation pattern 110 between a pair of the active pattern rows neighboring in the second direction D2.

In an example embodiment, the first mold layer 170 may not cover a portion of the gate insulation pattern 120 of each of the gate structures 160 that is adjacent to the end portion of the active pattern 105, and the second mold layer 175 may be spaced apart from the end portion of the active pattern 105 in the second direction D2.

An etching process using the first and second mold layers 170 and 175 as an etching mask may be performed to partially remove a portion of the upper portion of active pattern 105, a portion of the upper portion the isolation pattern 110 and a portion of an upper portion of the gate insulation pattern 120 exposed by the first opening 177, and thus the first opening 177 may be enlarged downwardly. During the etching process, an upper portion of each end portion of the active pattern 105 may be partially removed.

A doping process, for example, a gas phase doping (GPD) process may be performed on the end portions of the active pattern 105 exposed by the first opening 177 to form an impurity region 107.

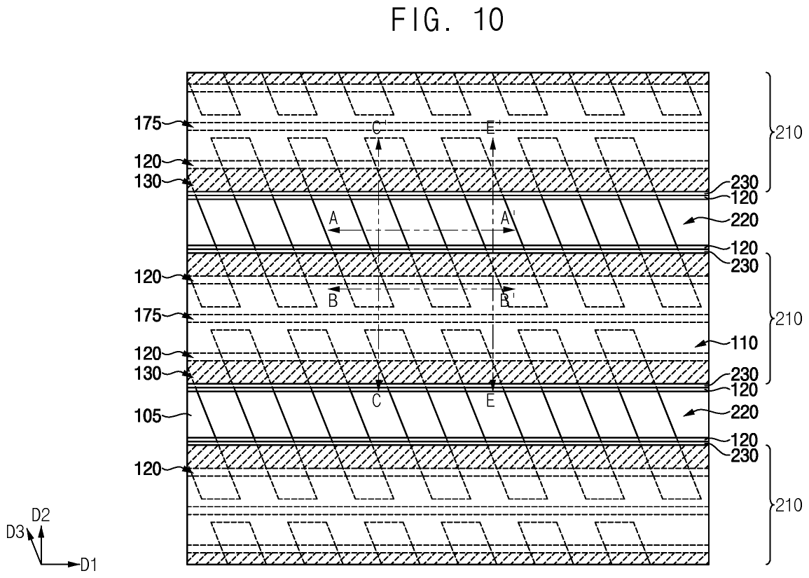

Referring to FIGS. 10 to 12, a third mold layer 180 may be formed on the active pattern 105, the isolation pattern 110, the gate insulation pattern 120 and the first and second mold layers 170 and 175 to fill the first opening 177. A planarization process may be performed on the third mold layer 180.

In example embodiments, the planarization process may include a chemical mechanical polishing (CMP) process and/or an etch-back process. As the planarization process is performed, the third mold layer 180 may be formed in the first opening 177, and may extend in the first direction D1.

First to third buffer layers 190, 200 and 210 may be sequentially stacked on the first to third mold layers 170, 175 and 180 in a vertical direction substantially perpendicular to the upper surface of the substrate 100. A second opening 220 may be formed through the first to third buffer layers 190, 200 and 210 and the first mold layer 170 to expose a portion of the upper surfaces of the active pattern 105 and the isolation pattern 110. The first buffer layer 190 may include an oxide, e.g., silicon oxide, the second buffer layer 200 may include, e.g., a high-k material, and the third buffer layer 210 may include an insulating nitride, e.g., silicon nitride.

In example embodiments, the second opening 220 may extend in the first direction D1 to expose the central portion of each of the active patterns 105 in the active pattern row, a portion of the isolation pattern 110 adjacent to the central portion of each of the active patterns 105 in the first direction D1, and a portion of the gate insulation pattern 120 neighboring the central portion of each of the active patterns 105 and the isolation pattern 110 in the second direction D2.

A first spacer layer may be formed on the active pattern 105, the isolation pattern 110 and the gate insulation pattern 120 exposed by the second opening 220 and the first to third buffer layers 190, 200 and 210. An anisotropic etching process may be performed on the first spacer layer to form a first spacer 230 on each of sidewalls of the second opening 220. The first spacer 230 may extend in the second direction D2. The first spacer 230 may include, e.g., silicon nitride, silicon oxycarbide (SiOC), silicon oxycarbonitride (SiOCN), etc.

Upper portions of the central portion of each of the active patterns 105, which is exposed by the second opening 220, the portion of the isolation pattern 110 adjacent to the central portion of each of the active patterns 105, and the portion of the gate insulation pattern 120 neighboring the central portion of each of the active patterns 105 and the isolation pattern 110, may be further removed so that the second opening 220 may be enlarged downwardly in the vertical direction.

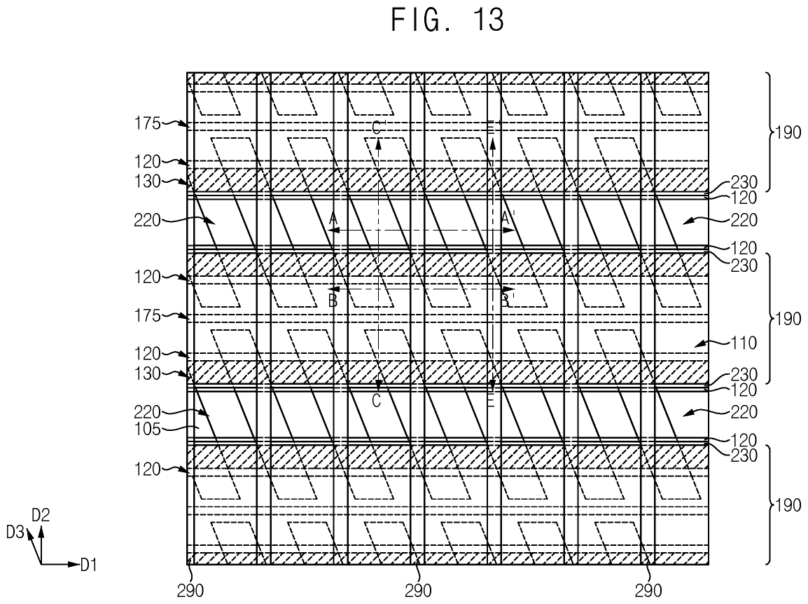

Referring to FIGS. 13 to 15, a pad layer, an ohmic contact layer and a second metal layer may be sequentially formed in the second opening 220. The pad layer may include, e.g., polysilicon doped with impurities. The ohmic contact layer may be formed by forming a first metal layer on the pad layer and performing a heat treatment process on the first metal layer. The first metal layer and the pad layer may be reacted with each other, thereby forming the ohmic contact layer. Thus, the ohmic contact layer may include a metal silicide, e.g., cobalt silicide, nickel silicide, titanium silicide, etc. The second metal layer may be formed on the ohmic contact layer.

In an alternative example embodiment, only a lower portion of the first metal layer may be reacted with the first pad layer to form the ohmic contact layer, and an upper portion of the first metal layer, that is not reacted with the first metal layer, may remain as the second metal layer.

A planarization process may be further performed on an upper portion of the second metal layer, and thus an upper surface of the second metal layer may be substantially coplanar with an upper surface of the third buffer layer 210.

A barrier layer, a third metal layer and a second mask layer may be sequentially stacked in the vertical direction on the third buffer layer 210, the second metal layer and the first spacer 230. The second mask layer may be patterned to form a second mask 290, and an etching process may be performed to pattern the third metal layer, the barrier layer and the third buffer layer 210 using the second mask 290 as an etching mask. Furthermore, the second metal layer, the ohmic contact layer and the pad layer may also be patterned.

Accordingly, the pad layer, the ohmic contact layer and the second metal layer may become a pad 240, an ohmic contact pattern 250 and a second metal pattern 260, respectively by the patterning. The pad 240, the ohmic contact pattern 250 and the second metal pattern 260 collectively form a first contact structure 268. In example embodiments, a plurality of first contact structures 268 may be spaced apart from each other in the first direction D1.

The barrier layer and the third metal layer may become a barrier pattern 270 and a third metal pattern 280, respectively by the patterning. The barrier pattern 270, the third metal pattern 280 and the second mask 290 sequentially stacked in the vertical direction may collectively form a bit line structure 300. In example embodiments, the bit line structure 300 may extend in the second direction D2, and a plurality of bit line structures 300 may be spaced apart from each other in the first direction D1.

The bit line structure 300, disposed in the second direction D2, may overlap the central portions of the active patterns 105 in a plan view. The first contact structure 268 may be interposed between the bit line structure 300 and corresponding one of the active patterns 105 to electrically connect the bit line structure 300 and corresponding one of the active patterns 105.

The second and the third buffer layers 200 and 210 may be patterned to form a second buffer 205 and a third buffer 215, respectively. The second buffer 205 and the third buffer 215 may be disposed under the bit line structure 300.

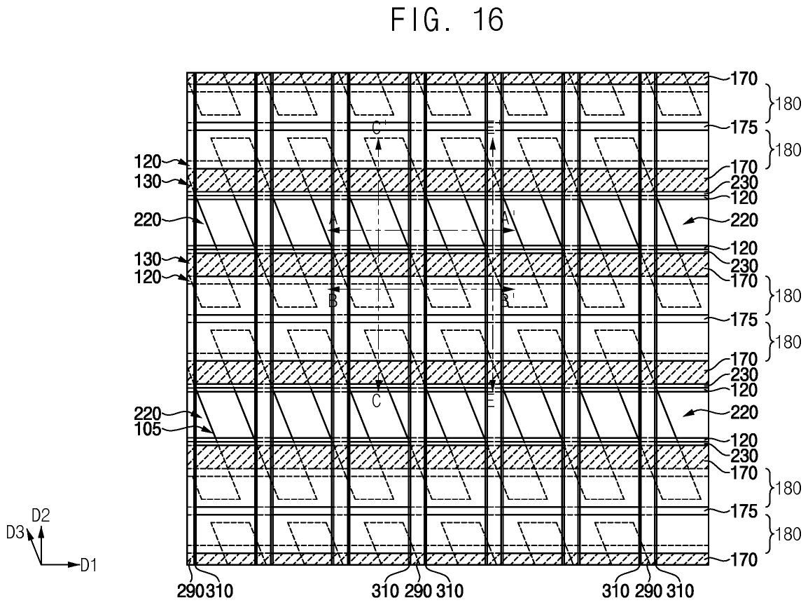

Referring to FIGS. 16 to 18, a second spacer layer may be formed on the bit line structure 300, the first contact structure 268, the second and third buffers 205 and 215, the first buffer layer 190 and the first spacer 230. The second spacer layer may be formed on a portion of the active pattern 105, a portion of the isolation pattern 110 and a portion of the gate insulation pattern 120, which are exposed by the second opening 220. An anisotropic etching process may be performed on the second spacer layer to form a second spacer 310 on the sidewalls of the bit line structure 300, the first contact structure 268 and the second and third buffers 205 and 215. The second spacer 310 may include an insulating nitride, e.g., silicon nitride.

An etching process, for example, a dry etching process or a wet etching process may be performed on the first buffer layer 190 to form a first buffer 195. The first buffer 195 may be disposed under the second buffer 205. The first to third buffers 195, 205 and 215, which are sequentially stacked in the vertical direction, may collectively form a buffer structure 218. In example embodiments, a plurality of buffer structures 218 may be spaced apart from each other by the first contact structure 268 and the first spacer 230 in the second direction D2. The plurality of buffer structures 218 may be disposed under the bit line structure 300.

As the etching process is performed, upper surfaces of portions of the first to third mold layers 170, 175 and 180, which may not be overlapped with the bit line structure 300 in the vertical direction, may be exposed.

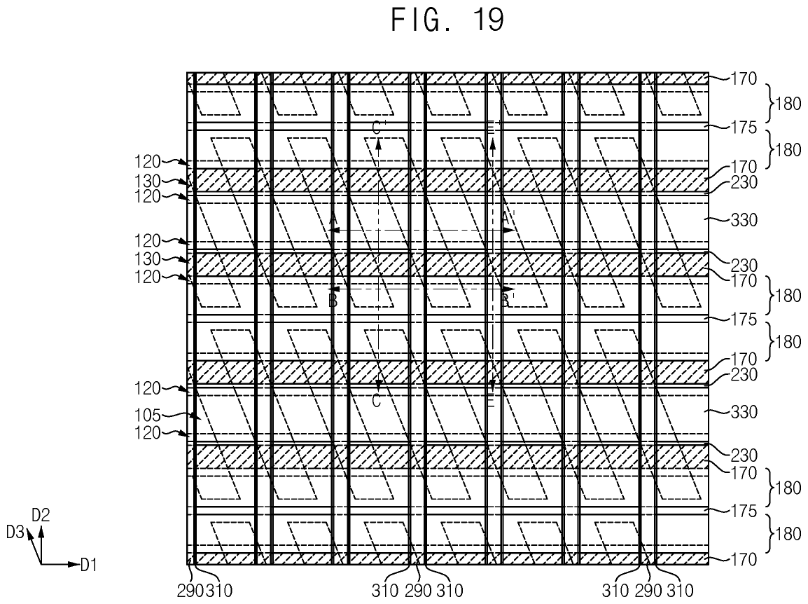

Referring to FIGS. 19 to 21, a filling pattern 330 may be formed in the second opening 220. In example embodiments, a filling layer is formed on the bit line structure 300, the second spacer 310, the first buffer 195, the first to third mold layers 170, 175 and 180, the first spacer 230, the active pattern 105, the isolation pattern 110 and the gate insulation pattern 120. The filling pattern 340 may be formed by performing an etching process on the filling layer.

Thus, the filling pattern 330 may be formed on upper surfaces of the active pattern 105, the isolation pattern 110 and the gate insulation pattern, which are 120 exposed by the second opening 220. The filling pattern 330 may contact a sidewall of a lower portion of the second spacer 310, which is on a sidewall of the first contact structure 268.

The filling pattern 330 may include, e.g., silicon nitride, silicon oxynitride, silicon oxycarbonitride, etc. In example embodiments, a plurality of filling patterns 330 may be spaced apart from each other in the first direction D1 by the first contact structure 268 and the lower portion of the second spacer 310 on each of the second openings 220. In example embodiments, an upper surface of the filling pattern 330 may be substantially coplanar with the upper surfaces of the active pattern 105 and the isolation pattern 110.

Referring to FIGS. 22 to 24, an upper portion of the filling pattern 330 may be removed by, e.g., an etch back process to form a third opening 365. A third spacer 350 may be formed on an outer sidewall of the second spacer 310, which is formed on each of opposite sidewalls in the first direction D1 of the bit line structure 300 and on each of opposite sidewalls in the first direction D1 of the first contact structure 268. An etching process may be performed using the bit line structure 300, the first contact structure 268, the second spacer and the third spacer 350 as an etching mask.

Thus, the third mold layer 180, an upper portion of the active pattern 105 and an upper portion of the isolation pattern 110 may be partially removed to form a fourth opening 360. During the etching process, the third mold layer 180, which extends in the first direction D1 at the previous stage of the manufacturing process, may be divided into a plurality of third molds 185 spaced apart from each other in the first direction D1. Each of the third molds 185 may be formed under corresponding one of the buffer structures 218. The third spacer 350 may include an oxide, e.g., silicon oxide.

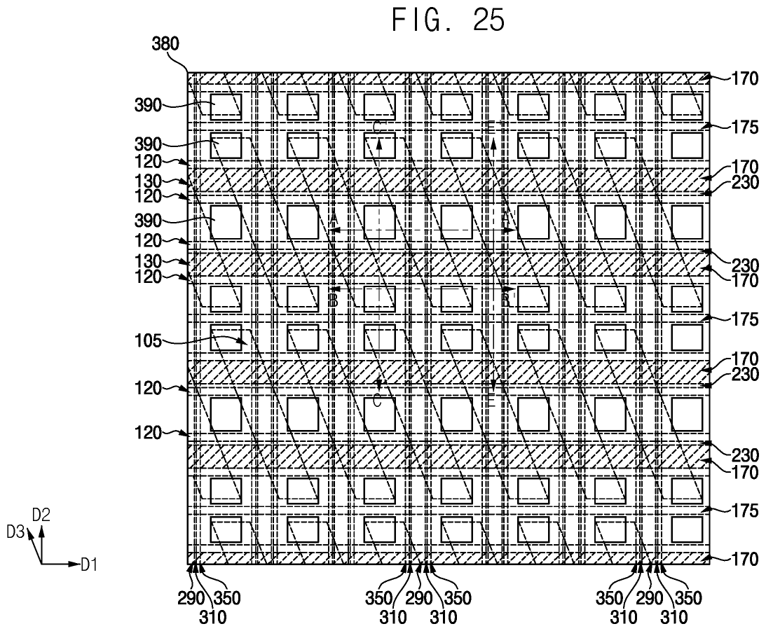

Referring to FIGS. 25 to 27, an etch stop layer 370 and a fourth spacer layer 380 may be sequentially stacked on upper surfaces and sidewalls of the active pattern 105 and the isolation pattern 110, which are exposed by the third and fourth openings 365 and 360. The etch stop layer 370 and the fourth spacer layer 380 may also be sequentially stacked on an upper surface of the filling pattern 330, an upper surface of the bit line structure 300, sidewalls of the third mold 185, the first spacer 230 and the gate insulation pattern 120. The etch stop layer 370 and the fourth spacer layer 380 may also be sequentially stacked on upper surfaces and sidewalls of the first and second mold layers 170 and 175. The etch stop layer 370 may include an oxide, e.g., silicon oxide, and the fourth spacer layer 380 may include an insulating nitride, e.g., silicon nitride, silicon oxynitride, etc.

A first sacrificial layer may be formed on the fourth spacer layer 380 to fill the third and fourth openings 365 and 360 by, e.g., a coating process. An upper portion of the first sacrificial layer may be removed by, e.g., an etch back process to form a first sacrificial pattern 390. In an example embodiment, an upper surface of the first sacrificial pattern 390 may be substantially coplanar with the upper surfaces of the active pattern 105 and the isolation pattern 110, however, the inventive concept may not be limited thereto. The first sacrificial pattern 390 may include, e.g., spin-on-hardmask (SOH), amorphous carbon layer (ACL), etc.

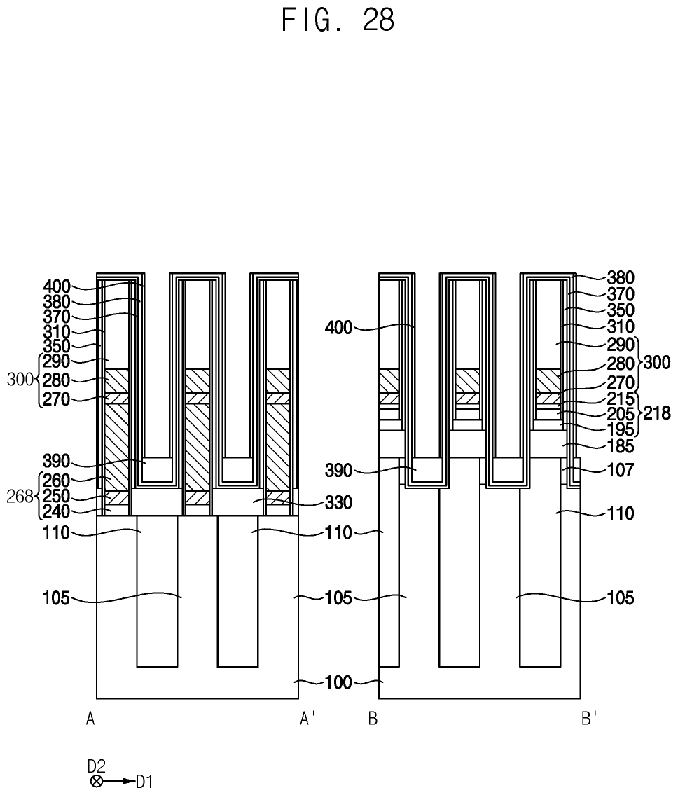

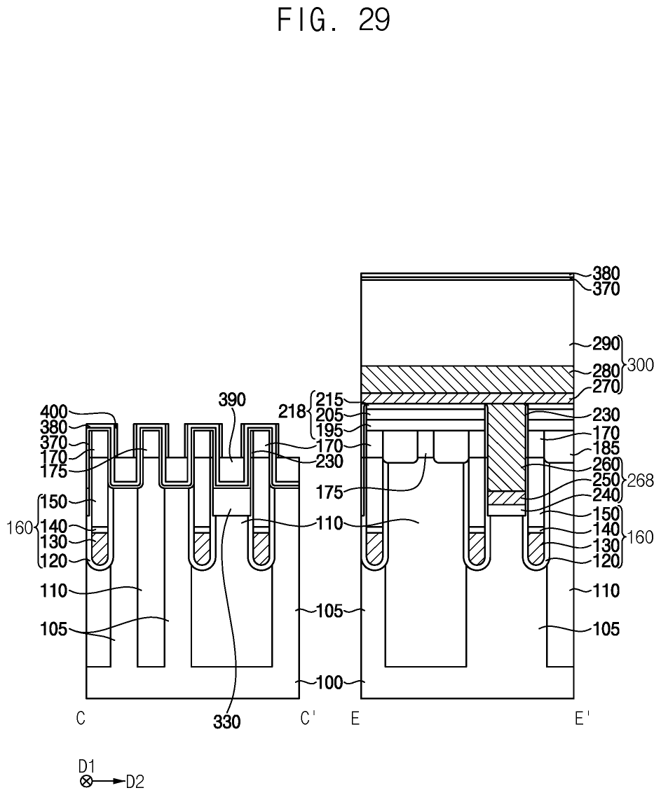

Referring to FIGS. 28 and 29, a second sacrificial layer may be formed on the fourth spacer layer 380 and the first sacrificial pattern 390, and may be anisotropically etched to form a second sacrificial pattern 400 on an upper sidewall of the fourth spacer layer 380. The second sacrificial pattern 400 may include an oxide, e.g., silicon oxide.

Referring to FIGS. 30 and 31, the first sacrificial pattern 390 may be removed by, e.g., an ashing process and/or a stripping process to form a fifth opening 410 exposing a surface of a lower portion of the fourth spacer layer 380. The lower portion of the fourth spacer layer 380 exposed by the fifth opening 410 may be additionally removed by a stripping process including a wet etching process using H₃PO₄ to expose a surface of the etch stop layer 370. During the stripping process, the upper surface of the filling pattern 330, which is covered by the etch stop layer 370, may not be removed. During the stripping process, a portion of the fourth spacer layer 380, which is covered by the second sacrificial pattern 400, may not be removed.

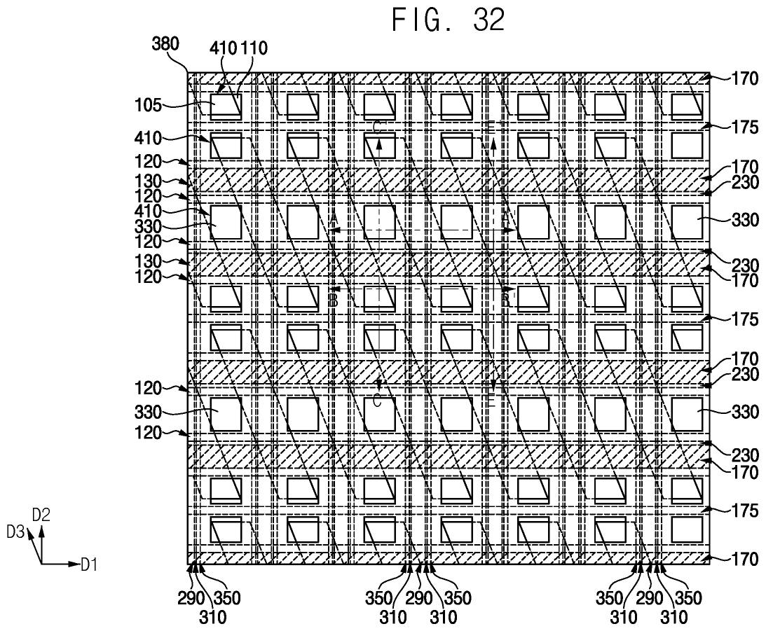

Referring to FIGS. 32 to 34, a lower portion of the etch stop layer 370 exposed by the fifth opening 410 may be removed by a stripping process including a wet etching process using, e.g., hydrogen fluoride (HF). Accordingly, the upper surfaces and the sidewalls of the active pattern 105 and the isolation pattern 110 and the upper surface of the filling pattern 330 may be exposed. During the stripping process, the second sacrificial pattern 400 on the sidewall of the fourth spacer layer 380 may also be removed.

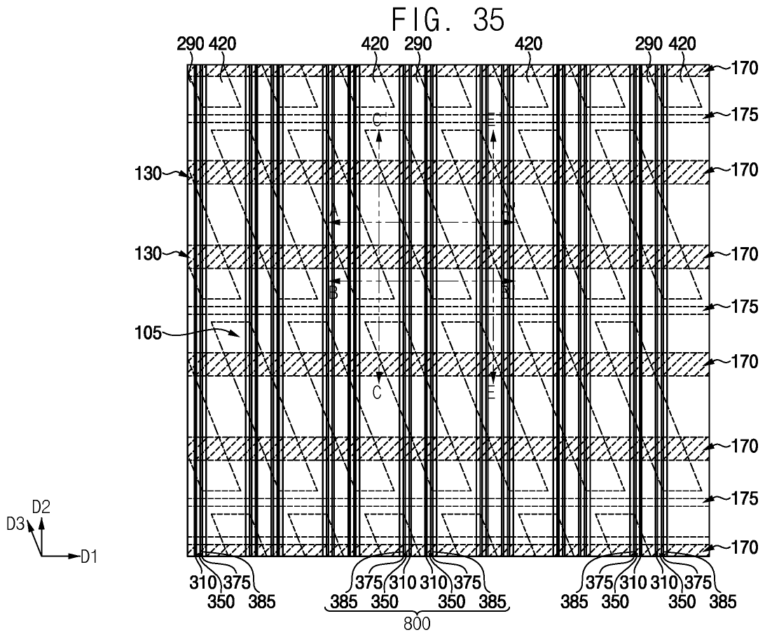

Referring to FIGS. 35 to 37, a cleaning process including a wet etching process may be performed on an inner wall of the fifth opening 410 to remove etching residue. A second contact structure layer 420 may be formed on the active pattern 105, the isolation pattern 110, the filling pattern 330 and the fourth spacer 385 to fill the fifth opening 410 and space between the bit line structures 300. The second contact structure layer 420 may be planarized until the upper surface of the bit line structure 300 is exposed.

During the planarization process, upper portions of the etch stop layer 370 and the fourth spacer layer 380 on the upper surface of the bit line structure 300 may also be removed to form an etch stop pattern 375 and a fourth spacer 385, respectively. Thus, the second spacer 310, the third spacer 350, the etch stop pattern 375 and the fourth spacer 385 may be sequentially stacked on each of opposite sidewalls in the first direction D1 of the bit line structure 300, which may collectively form a spacer structure 800, also described as a composite spacer 800. The individual spacers (i.e., second spacer 310, the third spacer 350, the etch stop pattern 375 and the fourth spacer 385) may make up the composite spacer 800. So, the individual spacers may be considered as sub-spacers.

The second contact structure layer 420 may extend in the second direction D2 between neighboring ones of the bit line structures 300 in the first direction D1, and a plurality of second contact structure layers 420 may be spaced apart from each other in the first direction D1. The second contact structure layer 420 may contact the upper surfaces of the active pattern 105, the isolation pattern 110 and the filling pattern 330, a sidewall of a lower portion of the third spacer 350 and a sidewall of the fourth spacer 385.

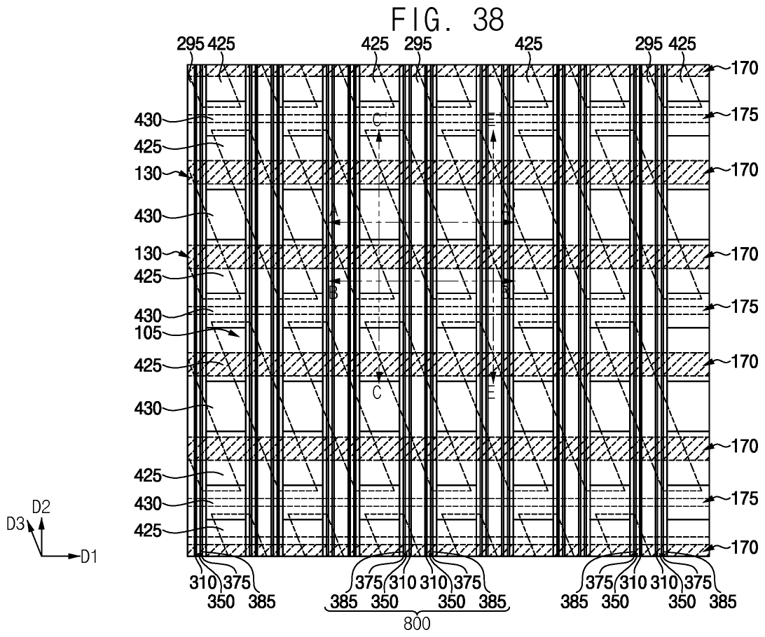

Referring to FIGS. 38 to 40, an etching mask (not shown in the drawings) having a sixth opening extending in the first direction D1 may be formed on the bit line structure 300, the spacer structure 800 and the second contact structure layer 420. The second contact structure layer 420 may be etched using the etching mask to form a seventh opening.

In example embodiments, the sixth opening may overlap in the vertical direction (i.e., in a plan view) the central portions of the active patterns 105. The sixth opening may be disposed extending in the first direction D1 and the second mold layer 175. Accordingly, the seventh opening may expose the upper surface of the filling pattern 330 and an upper surface of a portion of the fourth spacer 385 on the second mold layer 175.

By the etching process, the second contact structure layer 420, which extends in the second direction D2 at the previous stage of the manufacturing process, may be divided into a plurality of second contact structures 425 spaced apart from each other in the second direction D2. Each of the second contact structures 425 may contact an upper surface of corresponding one of the end portions of the active patterns 105. A fence pattern 430 may be formed to fill the seventh opening.

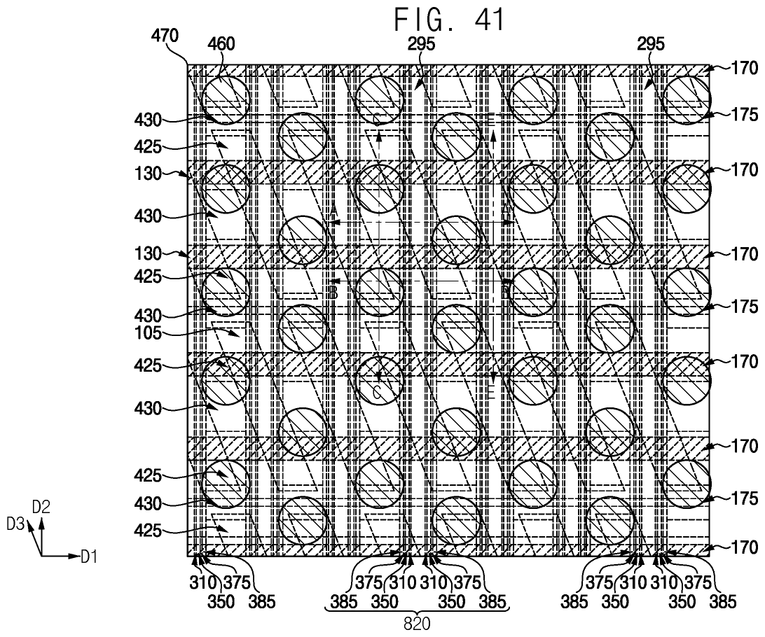

Referring to FIGS. 41 to 43, A landing pad layer is formed on the bit line structure 300, the spacer structure 800, the second contact structure 425 and the fence pattern 430. The landing pad layer, the bit line structure 300, the spacer structure 800, the second contact structure 425 and the fence pattern 430 may be partially removed to form a fourth recess. An insulation pattern 470 may be formed to fill the fourth recess.

Thus, the landing pad layer may be divided into a plurality of landing pads 460 spaced apart from each other in the first and second directions D1 and D2. Each of the landing pads 460 may contact an upper surface of a corresponding one of the second contact structures 425. In example embodiments, the landing pads 460 may be disposed in a honeycomb pattern in a plan view. Alternatively, the landing pads 460 may be disposed in a lattice pattern in a plan view.

Referring back to FIGS. 1 to 3, a first electrode 480 may be formed on the landing pad 460, a dielectric layer 490 may be formed on the first electrode 480 and the insulation pattern 470, and a second electrode 500 may be formed on the dielectric layer 490. The first electrode 480, the dielectric layer 490 and the second electrode 500 may collectively form a capacitor 510. By the above processes, the semiconductor device may be manufactured.

As illustrated above, the second and third spacers 310 and 350 may be formed on the sidewall of the bit line structure 300. The etching process may be performed using the bit line structure 300 and the second and third spacers 310 and 350 as an etching mask to form the fourth opening 360 exposing the upper surface of the active pattern 105. The etch stop layer 370 and the fourth spacer layer 380 may be sequentially stacked. The first sacrificial pattern 390 may be formed on the fourth spacer layer 380 to fill the fourth opening 360.

The second sacrificial pattern 400 may be formed on the sidewall of the fourth spacer layer 380. The first sacrificial pattern 390 may be removed to form the fifth opening 410. The lower portions of the fourth spacer layer 380 and the etch stop layer 370 may be sequentially removed to enlarge the fifth opening 410 so that the upper surface of the active pattern 105 may be exposed. The cleaning process may be performed to remove the residue on the inner wall of the fifth opening 410.

The second contact structure layer 420 may be formed to fill the fifth opening 410, and may be divided by the etching process to form the second contact structure 425 contacting the upper surface of the end portion of the active pattern 105.

If openings are formed to expose the upper surfaces of the end portions of the active pattern 105 by an etching process using the bit line structure 300 and the spacer structure 800 (i.e., the second to fourth spacers 310, 350 and 385 and the etch stop pattern 375) as an etching mask, a space between neighboring ones of the bit line structures 300 is small such that the etching process for forming the openings cannot be easily performed. Accordingly, heights of bottoms of the openings (and heights of bottoms of a contact structure layer filling the openings) may not be uniform.

However, in example embodiments, after the second and third spacers 310 and 350 may be formed on the sidewall of the bit line structure 300, the fourth openings 360 may be formed to expose the upper surfaces of the end portions of the active patterns 105 by the etching process using the bit line structure 300 and the second and third spacers 310 and 350 as an etching mask. Accordingly, the space between neighboring ones of the bit line structures 300 may be large, and thus the fourth openings 360 may be easily formed.

Additionally, the first sacrificial pattern 390 in the fourth opening 360 may be easily removed by an ashing process and/or a stripping process, and the lower portions of the fourth spacer layer 380 and the etch stop layer 370 in the fourth opening 360 may be easily removed by, e.g., a wet etching process. Accordingly, heights of bottoms of the fifth openings 410 may be uniform.

Furthermore, after forming the fifth openings 410, the cleaning process may be performed to remove the etching residue, so that the uniformity of the heights of the bottoms of the fifth openings 410 may be enhanced.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

Terms such as “same,” or “coplanar,” “parallel,” “perpendicular,” “perpendicular” as used herein when referring to orientation, layout, location, shapes, sizes, compositions or other measures do not necessarily mean an exactly identical orientation, layout, location, shapes, sizes, compositions or other measures, but are intended to encompass nearly identical location compositions or other measures within acceptable variations that may occur, for example, due to manufacturing processes. The term “substantially” may be used herein to emphasize this meaning, unless the context or other statements indicate otherwise. For example, items described as “substantially the same,” “substantially parallel,” or “substantially coplanar,” may be exactly the same, parallel, or perpendicular, or may be the same, parallel, or coplanar within acceptable variations that may occur, for example, due to manufacturing processes.

Although the figures described herein may be referred to using language such as “one embodiment,” or “certain embodiments,” these figures, and their corresponding descriptions are not intended to be mutually exclusive from other figures or descriptions, unless the context so indicates. Therefore, certain aspects from certain figures may be the same as certain features in other figures, and/or certain figures may be different representations or different portions of a particular exemplary embodiment.

It will be understood that when an element is referred to as being “on” another element, it can be directly on the other element or intervening elements may be present. In contrast, when an element is referred to as “contacting” or “in contact with” another element (or using any form of the word “contact”), there are no intervening elements present at the point of contact.

What is claimed is:

1. A semiconductor device comprising:
an active pattern on a substrate;
a first conductive contact on a central portion of the active pattern;
a bit line structure on the first conductive contact;
a spacer structure on sidewalls of the bit line structure and on sidewalls of the first conductive contact, the spacer structure including a first spacer, a second spacer, an etch stop pattern and a third spacer sequentially stacked in a horizontal direction parallel to an upper surface of the substrate;
a second conductive contact on an end portion of the active pattern; and
a capacitor on the second conductive contact,
wherein a lowermost surface of the first spacer is lower than a lowermost surface of the second spacer, and lower surfaces of the etch stop pattern and the third spacer are higher than the lowermost surface of the second spacer.

2. The semiconductor device according to claim 1, wherein the lower surface of the etch stop pattern is coplanar with the lower surface of the third spacer.

3. The semiconductor device according to claim 1, wherein the lowermost surface of the second spacer is coplanar with a lower surface of the second conductive contact.

4. The semiconductor device according to claim 1, wherein the second conductive contact includes a lower portion and an upper portion arranged along a vertical direction perpendicular to the upper surface of the substrate, and
wherein a width of the upper portion of the second conductive contact in the first horizontal direction is less than a width of the lower portion of the second conductive contact in the first horizontal direction.

5. The semiconductor device according to claim 4, wherein the lower surfaces of the etch stop pattern and the third spacer contact an upper surface of the lower portion of the second conductive contact.

6. The semiconductor device according to claim 4, further comprising a fence pattern including a lower portion and an upper portion arranged along the vertical direction,
wherein a width of the upper portion of the fence pattern in the first horizontal direction is less than a width of the lower portion of the fence pattern in the first horizontal direction.

7. The semiconductor device according to claim 6, wherein lowermost and uppermost surfaces of the fence pattern are coplanar with lowermost and uppermost surfaces of the second conductive contact, respectively.

8. The semiconductor device according to claim 1, further comprising a buffer stack between the substrate and the bit line structure, an upper surface of the buffer stack being coplanar with an upper surface of the first conductive contact,
wherein the bit line structure extends in a second direction parallel to the upper surface of the substrate, and the spacer structure is disposed on each of opposite sidewalls of the bit line structure and the first conductive contact in a first direction parallel to the upper surface of the substrate and intersecting the second direction.

9. The semiconductor device according to claim 8, wherein a lower surface of the buffer stack is higher than a lower surface of the first conductive contact.

10. The semiconductor device according to claim 8, wherein the buffer stack includes a first buffer, a second buffer and a third buffer sequentially stacked in a vertical direction perpendicular to the upper surface of the substrate, and
wherein the first spacer is disposed on an upper surface of the first buffer, and contacts each of opposite sidewalls in the first direction of the second and third buffers.

11. The semiconductor device according to claim 10, wherein the second spacer contacts a sidewall of the first spacer and a sidewall of the first buffer in the first direction.

12. The semiconductor device according to claim 10, further comprising a mold between the substrate and the buffer stack,
wherein the etch stop pattern contacts a sidewall of the second spacer and a sidewall of the mold in the first direction.

13. A semiconductor device comprising:
an active pattern on a substrate;
a first conductive contact on a central portion of the active pattern;
a buffer stack on the substrate, the buffer stack being adjacent to the first conductive contact;
a bit line structure on the first conductive contact and the buffer stack;
a spacer structure on sidewalls of the bit line structure, the first conductive contact and the buffer stack, the spacer structure including a first spacer, a second spacer, an etch stop pattern and a third spacer sequentially stacked in a horizontal direction parallel to an upper surface of the substrate;
a second conductive contact on an end portion of the active pattern, the second conductive contact including a lower portion and an upper portion arranged along a vertical direction perpendicular to the upper surface of the substrate; and
a capacitor on the second conductive contact,
wherein the first spacer covers the sidewalls of the bit line structure, the sidewalls of the first conductive contact and an upper sidewall of the buffer stack, and the etch stop pattern and the third spacer contact an upper surface of the lower portion of the second conductive contact and cover a sidewall of the upper portion of the second conductive contact.

14. The semiconductor device according to claim 13, wherein the second spacer covers an upper sidewall of the first conductive contact, and
wherein a lowermost surface of the second spacer is coplanar with a lower surface of the lower portion of the second conductive contact.

15. The semiconductor device according to claim 13, further comprising a fence pattern including a lower portion and an upper portion arranged along the vertical direction,
wherein lowermost and uppermost surfaces of the fence pattern are coplanar with lowermost and uppermost surfaces of the second conductive contact, respectively.

16. A semiconductor device comprising:
active patterns on a substrate;
an isolation pattern on the substrate, the isolation pattern covering sidewalls of the active patterns;
gate structures spaced apart from each other in a second direction parallel to an upper surface of the substrate, each of the gate structures extending through the active patterns and an upper portion of the isolation pattern in a first direction parallel to the upper surface of the substrate and perpendicular to the second direction;
first conductive contacts on central portions of the active patterns, respectively;
second conductive contacts on end portions of the active patterns, respectively;
buffer stacks on the active patterns and the isolation pattern, the buffer stacks being disposed between the second conductive contacts;
bit line structures spaced apart from each other in the first direction, each of the bit line structures extending in the second direction on the first conductive contacts and the buffer stacks;
spacer structures on sidewalls in the first direction of the bit line structures, the first conductive contacts and the buffer stacks, each of the spacer structures including a first spacer, a second spacer, an etch stop pattern and a third spacer sequentially stacked in the first direction;
landing pads on the second conductive contacts, respectively; and
capacitors on the second conductive contacts, respectively,
wherein a lowermost surface of the first spacer is lower than a lowermost surface of the second spacer, and lower surfaces of the etch stop pattern and the third spacer are higher than the lowermost surface of the second spacer.

17. The semiconductor device according to claim 16, further comprising fence patterns on the active patterns and the isolation pattern, the fence patterns contacting a sidewall in the second direction of the second conductive contacts.

18. The semiconductor device according to claim 17, further comprising filling patterns between a portion of the isolation pattern and the fence patterns, the portion of the isolation pattern being adjacent to the central portion of the active patterns, and the filling patterns covering lower sidewalls of the first conductive contacts,
wherein upper surface of the central portion of each of the active patterns is lower than the end portions of the active patterns.

19. The semiconductor device according to claim 17, wherein:
each of the second conductive contacts includes a lower portion and an upper portion arranged along a vertical direction perpendicular to the upper surface of the substrate, the lower and upper portions having different widths in the first horizontal direction from one another;
each of the fence patterns includes a lower portion and an upper portion arranged along the vertical direction, the lower and upper portions having different widths in the first horizontal direction from one another; and
the lower and upper portions of the fence patterns are coplanar with the lower and upper portions of the second conductive contacts, respectively.

20. The semiconductor device according to claim 19, wherein lower surfaces of the etch stop patterns and lower surfaces of the third spacers are coplanar with upper surfaces of the lower portions of the second conductive contacts.
